(19) United States
(12) Patent Application Publication
(10) Pub. No.: US 2024/0407266 A1
(43) Pub. Date: Dec. 5, 2024

(54) PIEZOELECTRIC ELEMENT AND ELECTROACOUSTIC TRANSDUCER

(71) Applicant: FUJIFILM Corporation, Tokyo (JP)

(72) Inventor: Tetsu Miyoshi, Minamiashigara-shi (JP)

(73) Assignee: FUJIFILM Corporation, Tokyo (JP)

(21) Appl. No.: 18/799,540

(22) Filed: Aug. 9, 2024

Related U.S. Application Data
(63) Continuation of application No. PCT/JP2023/000622, filed on Jan. 12, 2023.

(30) Foreign Application Priority Data
Feb. 10, 2022 (JP) 2022-019704
Nov. 1, 2022 (JP) 2022-175334

(51) Int. Cl. H10N 30/87; H04R 17/00; H10N 30/045; H10N 30/85; H10N 30/88

(52) U.S. Cl. CPC H10N 30/874; H04R 17/005; H10N 30/045; H10N 30/852; H10N 30/871; H10N 30/877; H10N 30/883

(57) ABSTRACT

Provided are a piezoelectric element and an electroacoustic transducer, which can be made thinner while ensuring piezoelectric characteristics in a piezoelectric element. The piezoelectric element includes a common electrode layer, a first piezoelectric layer which consists of a polymer-based piezoelectric composite material containing piezoelectric particles in a matrix containing a polymer material and is provided on one surface of the common electrode layer, a first electrode layer which is provided on a surface of the first piezoelectric layer on a side opposite to the common electrode layer, a first protective layer which is provided on a surface of the first electrode layer on a side opposite to the first piezoelectric layer, a second piezoelectric layer which consists of a polymer-based piezoelectric composite material containing piezoelectric particles in a matrix containing a polymer material and is provided on the other surface of the common electrode layer, a second electrode layer which is provided on a surface of the second piezoelectric layer on a side opposite to the common electrode layer, and a second protective layer which is provided on a surface of the second electrode layer on a side opposite to the second piezoelectric layer.

### CROSS-REFERENCE TO RELATED APPLICATIONS

This application is a Continuation of PCT International Application No. PCT/JP2023/000622 filed on Jan. 12, 2023, which claims priority under 35 U.S.C. § 119(a) to Japanese Patent Application No. 2022-019704 filed on Feb. 10, 2022 and Japanese Patent Application No. 2022-175334 filed on Nov. 1, 2022. The above applications are hereby expressly incorporated by reference, in their entirety, into the present application.

### BACKGROUND OF THE INVENTION

### 1. Field of the Invention

The present invention relates to a piezoelectric element and an electroacoustic transducer.

### 2. Description of the Related Art

A piezoelectric element, so-called an exciter, which is brought into contact and attached to various articles and vibrates the articles to generate a sound, has been used for various applications. For example, instead of a speaker, a sound can be generated by attaching the exciter to an image display panel, a screen, or the like and vibrating them.

As the piezoelectric element, it has been proposed to use a piezoelectric film in which a piezoelectric layer is sandwiched between an electrode layer and a protective layer. In addition, it has been also proposed to laminate the piezoelectric film in a plurality of layers and to use the laminate as the piezoelectric element.

For example, WO2020/196850A discloses a piezoelectric film including a polymer-based piezoelectric composite material in which piezoelectric particles are dispersed in a matrix containing a polymer material, and electrode layers formed on both surfaces of the polymer-based piezoelectric composite material, in which a loss tangent at a frequency of 1 kHz according to a dynamic viscoelasticity measurement has a maximal value of 0.1 or more in a temperature range of higher than 50° C. and 150° C. or lower, and has a value of 0.08 or more at 50° C. In addition, WO2020/196850A discloses a piezoelectric element in which the piezoelectric film is laminated in a plurality of layers by folding the piezoelectric film one or more times.

### SUMMARY OF THE INVENTION

The piezoelectric element formed by folding the piezoelectric film is attached to a vibration plate and vibrates the vibration plate to generate a sound from the vibration plate. In this case, the vibration plate can be efficiently bent by setting a spring constant of the piezoelectric element to approximately 0.1 times to 10 times a spring constant of the vibration plate. In order to set the spring constant of the piezoelectric element to be within the range, it is necessary to increase a thickness of the piezoelectric element to some extent. On the other hand, as the piezoelectric layer in the piezoelectric film is thicker, a voltage (potential difference) required to stretch and contract the piezoelectric film by the same amount is increased. Therefore, by making the piezoelectric film thinner and laminating a plurality of thin piezoelectric films, it is possible to ensure the spring constant as the piezoelectric element while ensuring the amount of stretch and contraction even at a low voltage.

However, according to the studies of the present inventor, as the number of lamination of the piezoelectric film increases, the number of adhesive layers for bonding the piezoelectric films to each other also increases, and the thickness of the piezoelectric element is increased by the thickness of the adhesive layers, which causes a problem that a space cannot be secured in a case of being incorporated into various thin devices.

It is also conceivable to reduce the thickness of the adhesive layer, but as the adhesive layer is thinner, adhesion is also reduced, which makes it difficult to ensure sufficient reliability.

An object of the present invention is to solve the problems of the related art, and to provide a piezoelectric element and an electroacoustic transducer, which can be made thinner while ensuring piezoelectric characteristics in a piezoelectric element obtained by laminating a piezoelectric film.

In order to solve the above-described problems, the present invention has the following configuration.

[1] A piezoelectric element comprising:
a common electrode layer;
a first piezoelectric layer which consists of a polymer-based piezoelectric composite material containing piezoelectric particles in a matrix containing a polymer material and is provided on one surface of the common electrode layer;
a first electrode layer which is provided on a surface of the first piezoelectric layer on a side opposite to the common electrode layer;
a first protective layer which is provided on a surface of the first electrode layer on a side opposite to the first piezoelectric layer;
a second piezoelectric layer which consists of a polymer-based piezoelectric composite material containing piezoelectric particles in a matrix containing a polymer material and is provided on the other surface of the common electrode layer;
a second electrode layer which is provided on a surface of the second piezoelectric layer on a side opposite to the common electrode layer; and
a second protective layer which is provided on a surface of the second electrode layer on a side opposite to the second piezoelectric layer.

[2] The piezoelectric element according to [1],
in which the first piezoelectric layer and the second piezoelectric layer are an integrated piezoelectric layer,
the first electrode layer and the second electrode layer are an integrated electrode layer,
the first protective layer and the second protective layer are an integrated protective layer, and
a laminate of the piezoelectric layer, the electrode layer, and the protective layer is folded to sandwich the common electrode layer.

[3] The piezoelectric element according to [1] or [2],
in which the first piezoelectric layer and the second piezoelectric layer are polarized in a thickness direction, and
a polarization direction in the first piezoelectric layer and a polarization direction in the second piezoelectric layer are opposite to each other.

[4] The piezoelectric element according to any one of [1] to [3],
in which a thickness of the common electrode layer is 10 μm or less.

[5] The piezoelectric element according to any one of [1] to [4],
in which the common electrode layer consists of a metal material, and
crystal grains of the metal material are connected to each other from one surface of the common electrode layer to the other surface.

[6] The piezoelectric element according to any one of [1] to [5],
in which the common electrode layer has no interface in a case of being viewed in a cross section perpendicular to a thickness direction.

[7] The piezoelectric element according to [1] to [6],
in which a sheet resistance of the common electrode layer is 100 m (milli)Ω/□ or less.

[8] A piezoelectric element obtained by laminating two or more of the piezoelectric elements according to any one of [1] to [7].

[9] The piezoelectric element according to [1] to [8], further comprising:
a hole portion which penetrates the first protective layer, the first electrode layer, and the first piezoelectric layer or penetrates the second protective layer, the second electrode layer, and the second piezoelectric layer to expose the common electrode layer; and
a conductive member which is electrically connected to the common electrode layer in the hole portion and is provided to cover a part of a surface of the first protective layer or a part of a surface of the second protective layer.

[10] The piezoelectric element according to [9], further comprising:
an insulating layer which is provided between the first electrode layer and the conductive member or between the second electrode layer and the conductive member and is exposed on a side surface of the hole portion.

[11] The piezoelectric element according to any one of [1] to [10], further comprising:
a second hole portion which exposes, from one side of the first protective layer or the second protective layer, an electrode layer adjacent to the other side; and
a second conductive member which is electrically connected to the electrode layer in the second hole portion and is provided to cover a part of a surface of the protective layer on the one side.

[12] The piezoelectric element according to [11], further comprising:
an insulating layer which is provided between the first electrode layer and the second conductive member or between the second electrode layer and the second conductive member and is exposed on a side surface of the second hole portion.

[13] An electroacoustic transducer obtained by attaching the piezoelectric element according to any one of [1] to [12] to a vibration plate.

[14] The electroacoustic transducer according to [13], further comprising:
a bonding layer which bonds the piezoelectric element and the vibration plate to each other,
in which a Young's modulus of the bonding layer is 0.1 GPa to 10 GPa.

According to the present invention, it is possible to provide a piezoelectric element and an electroacoustic transducer, which can be made thinner while ensuring piezoelectric characteristics in a piezoelectric element.

### BRIEF DESCRIPTION OF THE DRAWINGS

FIG. 1 is a view schematically showing an example of an electroacoustic transducer including a piezoelectric element according to an embodiment of the present invention.

FIG. 2 is a view schematically showing another example of the piezoelectric element according to the embodiment of the present invention.

FIG. 3 is a view schematically showing another example of the piezoelectric element according to the embodiment of the present invention.

FIG. 4 is a view schematically showing another example of the piezoelectric element according to the embodiment of the present invention.

FIG. 5 is a partially enlarged view showing a part of the piezoelectric element in an enlarged manner.

FIG. 6 is a conceptual view for describing an example of a production method of the piezoelectric element shown in FIG. 1.

FIG. 7 is a conceptual view for describing an example of the production method of the piezoelectric element shown in FIG. 1.

FIG. 8 is a conceptual view for describing an example of the production method of the piezoelectric element shown in FIG. 1.

FIG. 9 is a conceptual view for describing an example of the production method of the piezoelectric element shown in FIG. 1.

FIG. 10 is a perspective view schematically showing another example of the piezoelectric element according to the embodiment of the present invention.

FIG. 11 is a side view of the piezoelectric element shown in FIG. 10.

FIG. 12 is a perspective view schematically showing another example of the piezoelectric element according to the embodiment of the present invention.

FIG. 13 is a side view of the piezoelectric element shown in FIG. 16.

FIG. 14 is a conceptual view for describing an example of a production method of the piezoelectric element shown in FIG. 10.

FIG. 15 is a conceptual view for describing an example of the production method of the piezoelectric element shown in FIG. 10.

FIG. 16 is a conceptual view for describing an example of the production method of the piezoelectric element shown in FIG. 10.

FIG. 17 is a conceptual view for describing an example of the production method of the piezoelectric element shown in FIG. 10.

FIG. 18 is a diagram showing a configuration of the piezoelectric element according to the embodiment of the present invention as a circuit diagram.

FIG. 19 is a diagram showing a configuration of a piezoelectric element in the related art as a circuit diagram.

FIG. 20 is an enlarged cross-sectional view of a part of another example of the piezoelectric element according to the embodiment of the present invention.

FIG. 21 is a conceptual view for describing an example of a production method of the piezoelectric element shown in FIG. 20.

FIG. 22 is a conceptual view for describing an example of the production method of the piezoelectric element shown in FIG. 20.

FIG. 23 is a conceptual view for describing an example of the production method of the piezoelectric element shown in FIG. 20.

FIG. 24 is a conceptual view for describing an example of the production method of the piezoelectric element shown in FIG. 20.

FIG. 25 is a conceptual view for describing an example of the production method of the piezoelectric element shown in FIG. 20.

### DESCRIPTION OF THE PREFERRED EMBODIMENTS

Hereinafter, the piezoelectric element and electroacoustic transducer according to the embodiments of the present invention will be described in detail based on suitable examples shown in the accompanying drawings.

Although configuration requirements to be described below are described based on representative embodiments of the present invention, the present invention is not limited to the embodiments.

Any numerical range expressed using “to” in the present specification refers to a range including the numerical values before and after the “to” as a lower limit value and an upper limit value, respectively.

### [Piezoelectric Element and Electroacoustic Transducer]

The piezoelectric element according to the embodiment of the present invention is a piezoelectric element including a common electrode layer, a first piezoelectric layer which consists of a polymer-based piezoelectric composite material containing piezoelectric particles in a matrix containing a polymer material and is provided on one surface of the common electrode layer, a first electrode layer which is provided on a surface of the first piezoelectric layer on a side opposite to the common electrode layer, a first protective layer which is provided on a surface of the first electrode layer on a side opposite to the first piezoelectric layer, a second piezoelectric layer which consists of a polymer-based piezoelectric composite material containing piezoelectric particles in a matrix containing a polymer material and is provided on the other surface of the common electrode layer, a second electrode layer which is provided on a surface of the second piezoelectric layer on a side opposite to the common electrode layer, and a second protective layer which is provided on a surface of the second electrode layer on a side opposite to the second piezoelectric layer.

In addition, the electroacoustic transducer according to the embodiment of the present invention is an electroacoustic transducer obtained by attaching the above-described piezoelectric element to a vibration plate.

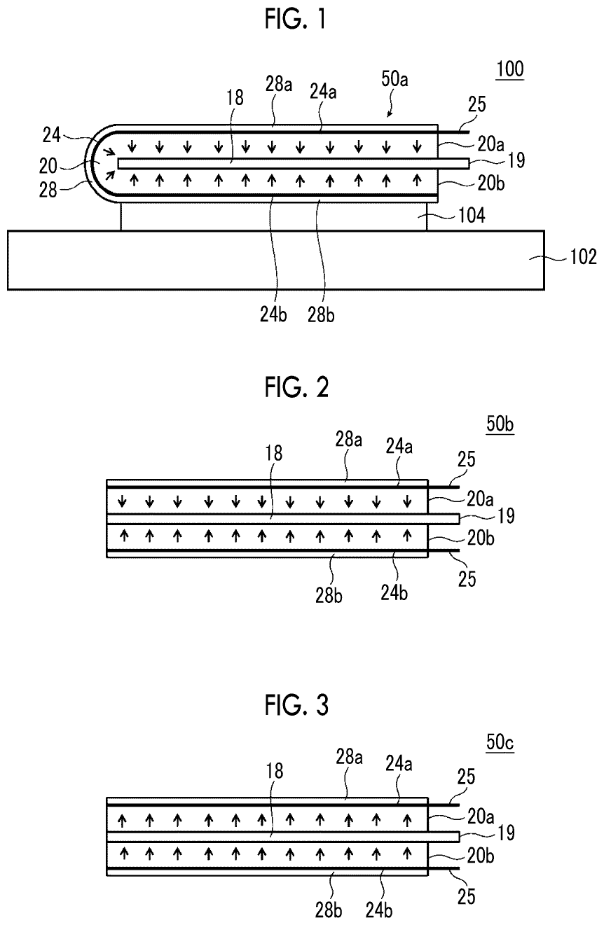

FIG. 1 shows a view schematically showing an example of the electroacoustic transducer including the piezoelectric element according to the embodiment of the present invention.

An electroacoustic transducer 100 shown in FIG. 1 includes a piezoelectric element 50a according to the embodiment of the present invention, a vibration plate 102, and an adhesive layer (bonding layer) 104 for bonding the piezoelectric element 50a and the vibration plate 102 to each other.

The piezoelectric element 50a shown in FIG. 1 includes a common electrode layer 18, a first piezoelectric layer 20a provided in contact with one main surface (upper surface in FIG. 1) of the common electrode layer 18, a first electrode layer 24a provided in contact with a surface of the first piezoelectric layer 20a on a side opposite to the common electrode layer 18, a first protective layer 28a provided in contact with a surface of the first electrode layer 24a on a side opposite to the first piezoelectric layer 20a, a second piezoelectric layer 20b provided in contact with the other main surface (lower surface in FIG. 1) of the common electrode layer 18, a second electrode layer 24b provided in contact with a surface of the second piezoelectric layer 20b on a side opposite to the common electrode layer 18, and a second protective layer 28b provided in contact with a surface of the second electrode layer 24b on a side opposite to the second piezoelectric layer 20b. That is, the piezoelectric element 50a has a laminated configuration in the order of the first protective layer 28a, the first electrode layer 24a, the first piezoelectric layer 20a, the common electrode layer 18, the second piezoelectric layer 20b, the second electrode layer 24b, and the second protective layer 28b.

In other words, the piezoelectric element 50a has a configuration in which two piezoelectric layers are interposed between the electrode layers and are laminated, and has a configuration in which the electrode layers on the piezoelectric layer side are shared by one common electrode layer 18.

In the piezoelectric element 50a shown in FIG. 1, the first piezoelectric layer 20a and the second piezoelectric layer 20b are an integrated piezoelectric layer 20, the first electrode layer 24a and the second electrode layer 24b are an integrated electrode layer 24, the first protective layer 28a and the second protective layer 28b are an integrated protective layer, and a laminate of the piezoelectric layer 20, the electrode layer 24, and the protective layer 28 is folded to sandwich the common electrode layer 18. In other words, in the folded piezoelectric layer 20, a region disposed on one main surface of the common electrode layer 18 corresponds to the first piezoelectric layer 20a in the present invention, and a region disposed on the other main surface of the common electrode layer 18 corresponds to the second piezoelectric layer 20b in the present invention. In addition, in the folded electrode layer 24, a region disposed on one main surface side of the common electrode layer 18 corresponds to the first electrode layer 24a in the present invention, and a region disposed on the other main surface side of the common electrode layer 18 corresponds to the second electrode layer 24b in the present invention. In addition, in the folded protective layer 28, a region disposed on one main surface side of the common electrode layer 18 corresponds to the first protective layer 28a in the present invention, and a region disposed on the other main surface side of the common electrode layer 18 corresponds to the second protective layer 28b in the present invention.

In the following description, in a case where it is not necessary to distinguish between the first piezoelectric layer 20a and the second piezoelectric layer 20b, the piezoelectric layers are collectively referred to as a piezoelectric layer. In addition, in a case where it is not necessary to distinguish between the first electrode layer 24a and the second electrode layer 24b, the electrode layers are collectively referred to as an electrode layer. In addition, in a case where it is not necessary to distinguish between the first protective layer 28a and the second protective layer 28b, the protective layer are collectively referred to as a protective layer.

The piezoelectric layer is a layer consisting of a polymer-based piezoelectric composite material containing piezoelectric particles in a matrix containing a polymer material. This point will be described in detail later, but by using the polymer-based piezoelectric composite material as the piezoelectric layer, it is possible to achieve both high piezoelectric characteristics and high flexibility.

In the piezoelectric element 50a, the common electrode layer 18 and the first electrode layer 24a are connected to an external power supply, and function as an electrode pair for applying a voltage to the first piezoelectric layer 20a. In addition, the common electrode layer 18 and the second electrode layer 24b are connected to an external power supply, and function as an electrode pair for applying a voltage to the second piezoelectric layer 20b. That is, the common electrode layer 18 acts as an electrode layer with respect to the two piezoelectric layers, and acts as an electrode pair which applies a voltage to the first piezoelectric layer 20a together with the first electrode layer 24a and also acts as an electrode pair which applies a voltage to the second piezoelectric layer 20b together with the second electrode layer 24b.

In the present invention, a thickness of the common electrode layer 18 is preferably 10 μm or less.

In a case where a voltage is applied to each piezoelectric layer, each piezoelectric layer stretches and contracts in a plane direction, and the piezoelectric element 50a stretches and contracts in the plane direction to bend the vibration plate 102 attached to the piezoelectric element 50a, and as a result, the vibration plate is vibrated in the thickness direction to generate a sound. The vibration plate is vibrated according to a magnitude of a driving voltage applied to the piezoelectric element 50a and generates the sound according to the driving voltage applied to the piezoelectric element 50a. That is, the piezoelectric element 50a can be used as an exciter.

Here, as described above, in a case where the piezoelectric element is used as the exciter which is attached to the vibration plate and vibrates the vibration plate, the piezoelectric element can efficiently bend the vibration plate by setting a spring constant of the piezoelectric element to approximately 0.1 times to 10 times a spring constant of the vibration plate. In order to set the spring constant of the piezoelectric element to be within the range, it is necessary to increase a thickness of the piezoelectric element to some extent. On the other hand, as the piezoelectric layer in the piezoelectric film is thicker, a voltage (potential difference) required to stretch and contract the piezoelectric film by the same amount is increased. Therefore, by making the piezoelectric film thinner and laminating a plurality of thin piezoelectric films, it is possible to ensure the spring constant as the piezoelectric element while ensuring the amount of stretch and contraction even at a low voltage.

However, as described above, as the number of lamination of the piezoelectric film increases, the number of adhesive layers for bonding the piezoelectric films to each other also increases, and the thickness of the piezoelectric element is increased by the thickness of the adhesive layers, which causes a problem that a space cannot be secured in a case of being incorporated into various thin devices.

On the other hand, the piezoelectric element 50a according to the embodiment of the present invention has a configuration in which the first piezoelectric layer 20a, the first electrode layer 24a, and the first protective layer 28a are laminated on one main surface side of the common electrode layer 18, the second piezoelectric layer 20b, the second electrode layer 24b, and the second protective layer 28b are laminated on the other main surface side of the common electrode layer 18, and one common electrode layer 18 shares one of the electrode layers constituting the electrode pair of each of the two piezoelectric layers.

Since the piezoelectric element 50a according to the embodiment of the present invention has such a configuration, a configuration can be adopted in which two layers of the piezoelectric layers are laminated without using an adhesive layer, so that a thickness of the piezoelectric element 50a can be reduced. In addition, since the two piezoelectric layers are laminated, the thickness of each piezoelectric layer can be reduced to secure the amount of stretch and contraction even at a low voltage, and the spring constant required for the piezoelectric element 50a can be secured.

In a case where the thickness of the piezoelectric element is the same as that in a case where two piezoelectric films are laminated using an adhesive layer in the related art, the thickness of the piezoelectric layer can be made thicker in the piezoelectric element according to the embodiment of the present invention, so that the piezoelectric characteristics can be further improved and a sound pressure of the electroacoustic transducer can be further improved.

Here, according to the studies of the present inventor, it has been found that the piezoelectric element according to the embodiment of the present invention has a lower relative permittivity than a piezoelectric element in the related art, in which two layers of piezoelectric films are laminated using an adhesive layer. Therefore, it has been found that the piezoelectric element according to the embodiment of the present invention has an effect of consuming less power and generating less heat as compared with the piezoelectric element in the related art.

Regarding this point, the present inventor has presumed as follows.

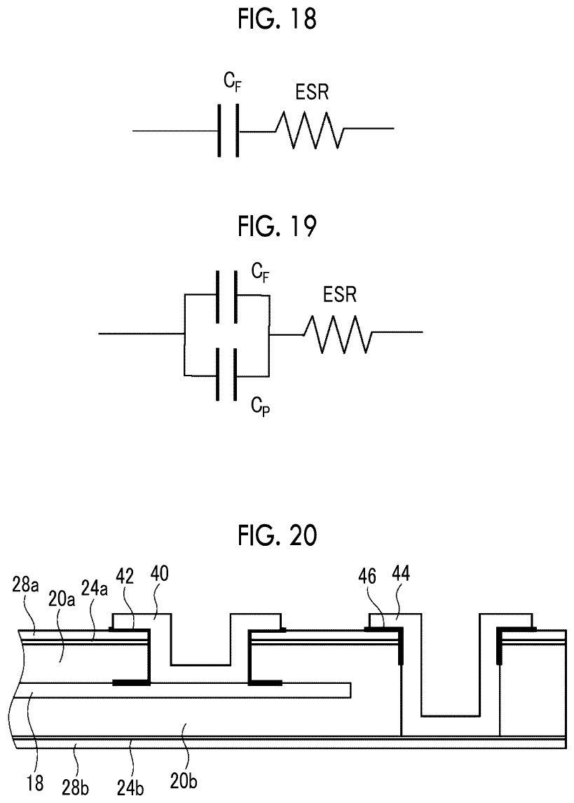

In a case where one piezoelectric film is schematically shown in a circuit diagram, as shown in FIG. 18, the piezoelectric film is represented by a capacity component C_{F} and a resistance component ESR. In a case of the piezoelectric element in the related art, in which the two piezoelectric films are laminated using an adhesive layer, a configuration of conductor (electrode layer)-insulator (adhesive layer)-conductor (electrode layer) is formed by the presence of the adhesive layer, so that a parasitic capacitance C_{P} is generated as shown in a circuit diagram of FIG. 19. Therefore, the relative permittivity is increased, the power consumption is increased as compared with a case of one sheet of the piezoelectric film, and heat is likely to be generated.

On the other hand, in the piezoelectric element according to the embodiment of the present invention, since the two layers of the piezoelectric layers are laminated without using an adhesive layer, the configuration of the conductor-insulator-conductor is not formed. Therefore, a circuit diagram of the piezoelectric element in this case is the same as that in FIG. 18. Accordingly, it is considered that the effect of consuming less power and generating less heat as compared with the piezoelectric element in the related art is obtained.

In addition, in a case where the thickness of the common electrode layer 18 is too large, the piezoelectric characteristics are lowered by constraining the stretch and contraction of the piezoelectric layer 20. On the other hand, by setting the thickness of the common electrode layer 18 to be 10 μm or less, it is possible to ensure the piezoelectric characteristics by suppressing the constrain of the stretch and contraction of the piezoelectric layer 20. In addition, the thickness of the piezoelectric element 50a can be reduced.

Here, a current twice as large as that in the first electrode layer and the second electrode layer flows through the common electrode layer 18. Therefore, in a case where the thickness is excessively reduced, the electric resistance is increased, which may cause a heat generation failure. Therefore, from the viewpoint of safety, a sheet resistance of the common electrode layer 18 is preferably 100 mΩ/□ (square) or less, more preferably 1 mΩ/□ to 100 mΩ/□, still more preferably 1 mΩ/□ to 50 mΩ/□, and still more preferably 1 mΩ/□ to 10 mΩ/□.

In order to realize the above-described sheet resistance value at the thickness of 10 μm or less, it is appropriate to use a metal material which is a good conductor in the common electrode layer. Specific examples thereof include a metal material such as copper, silver, gold, nickel, platinum, iridium, palladium, titanium, and aluminum, and an alloy material consisting of these metal materials. Among these, copper is preferable because it has low electric resistance and relatively excellent corrosion resistance.

In addition, from the viewpoint of sheet resistance, it is preferable that a metal foil constituting the common electrode layer 18 has no interface in a case of being viewed in a cross section in the thickness direction. In other words, it is preferable that the common electrode layer 18 consists of one metal foil or the like. For example, in a case where the common electrode layer 18 is formed by bonding a metal foil or bonding a metal foil with a conductive adhesive layer, even in the case of the same type of metal foil, a high-resistance interface is present at a bonded portion. In a case of having such an interface, the effective sheet resistance is increased. Therefore, it is preferable that the common electrode layer 18 does not have an interface in a case of being viewed in a cross section in the thickness direction.

The presence or absence of the interface of the common electrode layer 18 may be observed by an optical microscope.

In addition, in a case where the common electrode layer 18 consists of a metal material, whether or not the common electrode layer consists of one metal foil can also be determined by whether or not crystal grains of the metal material are connected to each other from one surface of the common electrode layer to the other surface.

In a case where the common electrode layer 18 consists of a metal material, it is possible to observe a cross section with an electron microscope to determine whether or not the crystal grains of the metal material are connected to each other from one surface of the common electrode layer to the other surface.

In addition, as will be described in detail later, it is preferable that the piezoelectric layer is subjected to a polarization treatment (poling) in a thickness direction. In FIG. 1, an arrow conceptually shows a direction of the polarization treatment of the piezoelectric layer. In the piezoelectric element shown in FIG. 1, since the piezoelectric layer is folded to sandwich the common electrode layer, a polarization direction in the first piezoelectric layer 20a and a polarization direction in the second piezoelectric layer 20b are opposite to each other in space. In other words, in a case where the common electrode layer 18 is used as a reference, the polarization direction in the first piezoelectric layer 20a and the polarization direction in the second piezoelectric layer 20b are the same direction with respect to the common electrode layer 18.

As a result, in a case where the voltage is applied to each piezoelectric layer, each piezoelectric layer stretches and contracts in the same direction, so that the amount of stretch and contraction as the piezoelectric element 50a can be increased, and high performance as the exciter can be obtained.

In the piezoelectric element, the polarization direction in the piezoelectric layer may be detected by a d33 meter or the like. Alternatively, the polarization direction in the piezoelectric layer may be known from polarization treatment conditions described later.

In addition, in the example shown in FIG. 1, the electrode layer 24 has a lead-out portion 25 electrically connected to a wiring line of the power supply, and the common electrode layer 18 has a lead-out portion 19 electrically connected to the wiring line of the power supply. The lead-out portion 25 is connected to a terminal of one polarity of the power supply, and the lead-out portion 19 is connected to a terminal of the other polarity of the power supply. In a case where the common electrode layer 18 is used as a reference, since the first piezoelectric layer 20a and the second piezoelectric layer 20b have the same polarization direction, and the common electrode layer 18 is supplied with power of the same polarity, the first piezoelectric layer 20a and the second piezoelectric layer 20b stretch and contract in the same direction.

In FIG. 1, the arrow is used for convenience to indicate the polarization direction, but the polarization direction is reversed depending on an orientation of electric field in a case of the polarization treatment. However, since AC signal is applied for operation in practice, there is no problem in orientation of the arrow.

Here, in the example shown in FIG. 1, the piezoelectric element 50a has a configuration in which the laminate of the piezoelectric layer 20, the electrode layer 24, and the protective layer 28 is folded to sandwich the common electrode layer 18, but the present invention is not limited thereto.

FIG. 2 shows a view schematically showing another example of the piezoelectric element according to the embodiment of the present invention.

A piezoelectric element 50b shown in FIG. 2 includes a common electrode layer 18, a first piezoelectric layer 20a provided on one main surface (upper surface in FIG. 2) of the common electrode layer 18, a first electrode layer 24a provided on a surface of the first piezoelectric layer 20a on a side opposite to the common electrode layer 18, a first protective layer 28a provided in contact with a surface of the first electrode layer 24a on a side opposite to the first piezoelectric layer 20a, a second piezoelectric layer 20b provided on the other main surface (lower surface in FIG. 2) of the common electrode layer 18, a second electrode layer 24b provided on a surface of the second piezoelectric layer 20b on a side opposite to the common electrode layer 18, and a second protective layer 28b provided on a surface of the second electrode layer 24b on a side opposite to the second piezoelectric layer 20b. In the example shown in FIG. 2, the first piezoelectric layer 20a and the second piezoelectric layer 20b are not integrated with each other, and are independent layers. In addition, the first electrode layer 24a and the second electrode layer 24b are not integrated with each other, and are independent layers. In addition, the first protective layer 28a and the second protective layer 28b are not integrated with each other, and are independent layers.

As described above, the piezoelectric element according to the embodiment of the present invention may have a configuration in which a sheet-like piezoelectric layer, electrode layer, protective layer, and common electrode layer are laminated.

In addition, in the example shown in FIG. 2, each of the first electrode layer 24a and the second electrode layer 24b has a lead-out portion 25 electrically connected to a wiring line of the power supply, and the common electrode layer 18 has a lead-out portion 19 electrically connected to the wiring line of the power supply.

In addition, in the example shown in FIG. 2, the piezoelectric layer is subjected to a polarization treatment in a thickness direction, and a polarization direction in the first piezoelectric layer 20a and a polarization direction in the second piezoelectric layer 20b are opposite to each other in space. That is, in a case where the common electrode layer 18 is used as a reference, the polarization direction in the first piezoelectric layer 20a and the polarization direction in the second piezoelectric layer 20b are the same direction with respect to the common electrode layer 18.

In addition, in the example shown in FIG. 2, the first electrode layer 24a and the second electrode layer 24b have the lead-out portion 25 electrically connected to a wiring line of the power supply, and the common electrode layer 18 has the lead-out portion 19 electrically connected to the wiring line of the power supply. The two lead-out portions 25 are connected in parallel to a terminal of one polarity of the power supply, and the lead-out portion 19 is connected to a terminal of the other polarity of the power supply. In a case where the common electrode layer 18 is used as a reference, since the first piezoelectric layer 20a and the second piezoelectric layer 20b have the same polarization direction, and the common electrode layer 18 is supplied with power of the same polarity, the first piezoelectric layer 20a and the second piezoelectric layer 20b stretch and contract in the same direction.

As a result, in a case where the voltage is applied to each piezoelectric layer, each piezoelectric layer stretches and contracts in the same direction, so that the amount of stretch and contraction as the piezoelectric element 50a can be increased, and high performance as the exciter can be obtained.

In the example shown in FIG. 2, in the configuration in which the sheet-like layers are laminated, the two piezoelectric layers are laminated such that the polarization directions thereof are opposite to each other in space, that is, laminated in the same direction in a case of being based on the common electrode layer 18, but the present invention is not limited thereto.

FIG. 3 shows a view schematically showing another example of the piezoelectric element according to the embodiment of the present invention.

A piezoelectric element 50c shown in FIG. 3 includes a common electrode layer 18, a first piezoelectric layer 20a provided on one main surface (upper surface in FIG. 3) of the common electrode layer 18, a first electrode layer 24a provided on a surface of the first piezoelectric layer 20a on a side opposite to the common electrode layer 18, a first protective layer 28a provided in contact with a surface of the first electrode layer 24a on a side opposite to the first piezoelectric layer 20a, a second piezoelectric layer 20b provided on the other main surface (lower surface in FIG. 3) of the common electrode layer 18, a second electrode layer 24b provided on a surface of the second piezoelectric layer 20b on a side opposite to the common electrode layer 18, and a second protective layer 28b provided on a surface of the second electrode layer 24b on a side opposite to the second piezoelectric layer 20b. In the example shown in FIG. 3, same as in FIG. 2, the first piezoelectric layer 20a and the second piezoelectric layer 20b are not integrated with each other, and are independent layers. In addition, the first electrode layer 24a and the second electrode layer 24b are not integrated with each other, and are independent layers. In addition, the first protective layer 28a and the second protective layer 28b are not integrated with each other, and are independent layers.

In addition, in the example shown in FIG. 3, each of the first electrode layer 24a and the second electrode layer 24b has a lead-out portion 25 electrically connected to a wiring line of the power supply, and the common electrode layer 18 has a lead-out portion 19 electrically connected to the wiring line of the power supply.

Here, in the example shown in FIG. 3, the piezoelectric layer is subjected to a polarization treatment in a thickness direction, and a polarization direction in the first piezoelectric layer 20a and a polarization direction in the second piezoelectric layer 20b are the same direction in space. That is, in a case where the common electrode layer 18 is used as a reference, the polarization direction in the first piezoelectric layer 20a and the polarization direction in the second piezoelectric layer 20b are opposite to each other with respect to the common electrode layer 18.

With the configuration, in a case where the two lead-out portions 25 are connected in parallel to a terminal of one polarity of the power supply and the lead-out portion 19 is connected to a terminal of the other polarity of the power supply, based on the common electrode layer 18 as a reference, since the first piezoelectric layer 20a and the second piezoelectric layer 20b have opposite polarization directions, and the common electrode layer 18 is supplied with power of the same polarity, the first piezoelectric layer 20a and the second piezoelectric layer 20b stretch and contract in opposite directions. That is, in a case where a voltage of a polarity in which the first piezoelectric layer 20a is stretched is applied, the second piezoelectric layer 20b is contracted; and in a case where a voltage of a polarity in which the first piezoelectric layer 20a is contracted is applied, the second piezoelectric layer 20b is stretched.

As a result, since the piezoelectric element 50c is bent to a large extent in the plane direction, the piezoelectric element 50c itself can be suitably used as an element which vibrates with bending vibration to generate a sound.

In addition, the piezoelectric element according to the embodiment of the present invention may have a configuration in which two or more of the above-described piezoelectric elements are laminated.

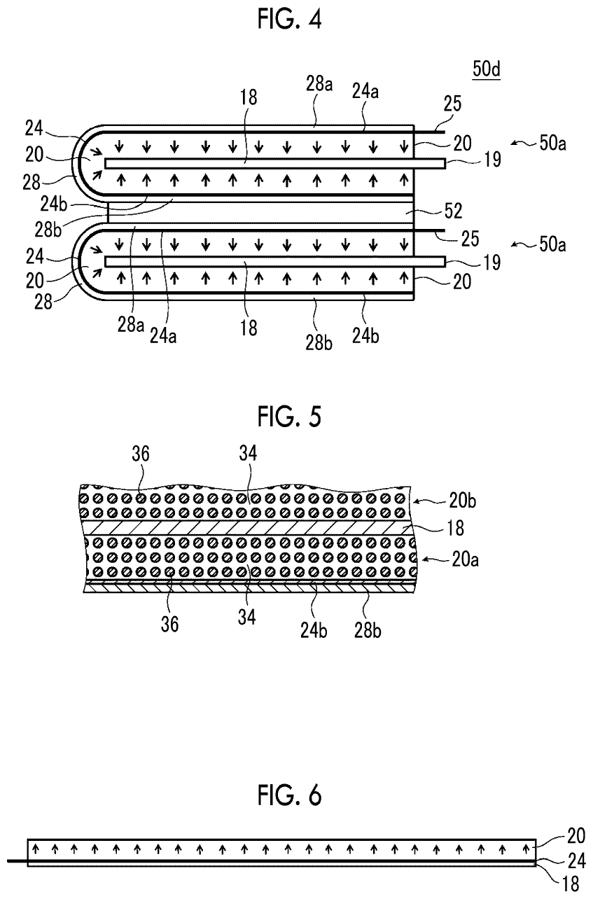

FIG. 4 is a view schematically showing another example of the piezoelectric element according to the embodiment of the present invention.

A piezoelectric element 50d shown in FIG. 4 has a configuration in which two of the piezoelectric elements 50a shown in FIG. 1 are laminated. The two piezoelectric elements 50a are bonded to each other using an adhesive layer 52. In addition, a thickness of the common electrode layer 18 in each piezoelectric element 50a is preferably 10 μm or less.

Since each piezoelectric element 50a has the same configuration as the piezoelectric element 50a shown in FIG. 1, the description thereof will be omitted.

In the example shown in FIG. 4, polarization directions of the piezoelectric layers in the two piezoelectric elements 50a have the same orientation as the corresponding common electrode layers 18.

As the adhesive layer 52, various known adhesive layers can be used as long as the piezoelectric elements 50a can be bonded to each other.

Specifically, an adhesive or pressure sensitive adhesive as an adhesive layer 104 described later, which is used for bonding the vibration plate 102 and the piezoelectric element 50, can be used.

A thickness of the adhesive layer 52 is not limited, and a thickness at which sufficient bonding strength (adhesive force or pressure sensitive adhesive force) can be obtained may be appropriately set depending on the material of the adhesive layer 52.

Here, in the piezoelectric element 50d, as the adhesive layer 52 is thinner, the transfer effect of stretch and contraction energy (vibration energy) of the piezoelectric element 50d to the vibration plate 102 is higher, and thus the energy efficiency can be increased. In addition, in a case where the adhesive layer 52 is thick and has high rigidity, there is a possibility that the stretch and contraction of the piezoelectric element 50d may be constrained.

In consideration of this point, it is preferable that the adhesive layer 52 is thin. Specifically, the thickness of the adhesive layer 52 is preferably 0.1 to 50 μm, more preferably 0.1 to 30 μm, and still more preferably 0.1 to 10 μm in terms of thickness after bonding.

In the piezoelectric element 50d, in a case where a voltage is applied to each piezoelectric layer, each piezoelectric layer stretches and contracts in a plane direction, and the piezoelectric element 50d stretches and contracts in the plane direction to bend the vibration plate attached to the piezoelectric element 50d, and as a result, the vibration plate is vibrated in the thickness direction to generate a sound. The vibration plate is vibrated according to a magnitude of a driving voltage applied to the piezoelectric element 50d and generates the sound according to the driving voltage applied to the piezoelectric element 50d. That is, the piezoelectric element 50d can be used as an exciter.

Such a piezoelectric element 50d has a configuration in which four layers of the piezoelectric layers are laminated.

In a case of the piezoelectric element in which four layers of the piezoelectric films are laminated, three adhesive layers are required for bonding the respective piezoelectric films to each other.

On the other hand, in the piezoelectric element 50d according to the embodiment of the present invention, since the number of adhesive layers is 1 even in the configuration including four layers of the piezoelectric layers, the thickness of the piezoelectric element 50d can be reduced by a thickness of two layers of the adhesive layers.

In addition, since the four piezoelectric layers are laminated, the thickness of each piezoelectric layer can be reduced to secure the amount of stretch and contraction even at a low voltage, and the spring constant required for the piezoelectric element 50d can be secured.

In addition, since the four piezoelectric layers are laminated, the thickness of each piezoelectric layer is reduced, and in a case where the thickness of the common electrode layer 18 is too large, the stretch and contraction of the piezoelectric layer 20 is constrained, resulting in a decrease in piezoelectric characteristics. On the other hand, by setting the thickness of the common electrode layer 18 to be 10 μm or less, it is possible to ensure the piezoelectric characteristics by suppressing the constrain of the stretch and contraction of the piezoelectric layer 20. In addition, the thickness of the piezoelectric element 50d can be reduced.

In the example shown in FIG. 4, the configuration in which two piezoelectric elements 50a are laminated is adopted, but the present invention is not limited thereto, and a configuration in which three or more piezoelectric elements 50a are laminated may be adopted. That is, the piezoelectric element may have a configuration in which the piezoelectric element includes six or more piezoelectric layers.

In addition, in the example shown in FIG. 4, two piezoelectric elements 50a in which the piezoelectric layer 20 is folded to sandwich the common electrode layer 18 are laminated as shown in FIG. 1, but the present invention is not limited thereto. For example, a configuration in which two laminated piezoelectric elements 50b of laminating sheet-like layers are laminated, as shown in FIG. 2, may be adopted, or a configuration that two laminated piezoelectric elements 50c in which the polarization directions of the two piezoelectric layers are the same in space are laminated, as shown in FIG. 3, may be adopted. Alternatively, a configuration in which the piezoelectric element 50a shown in FIG. 1 and the piezoelectric element 50b shown in FIG. 2 are laminated may be adopted, a configuration in which the piezoelectric element 50a shown in FIG. 1 and the piezoelectric element 50c shown in FIG. 3 are laminated may be adopted, or a configuration in which the piezoelectric element 50b shown in FIG. 2 and the piezoelectric element 50c shown in FIG. 3 are laminated may be adopted.

Hereinafter, constituent elements of the piezoelectric element according to the embodiment of the present invention will be described. In the following description, the piezoelectric elements 50a to 50d are also collectively referred to as a piezoelectric element 50 in a case where it is not necessary to distinguish therebetween.

FIG. 5 shows an enlarged view of a part of the piezoelectric layer 20 in the piezoelectric element 50.

In the present invention, the piezoelectric layer 20 is a polymer-based piezoelectric composite material containing piezoelectric particles 36 in a matrix 34 containing a polymer material, as conceptually shown in FIG. 5.

As a material of the matrix 34 (serving as a matrix and a binder) of the polymer-based piezoelectric composite material constituting the piezoelectric layer 20, it is preferable to use a polymer material having viscoelasticity at normal temperature. In the present specification, the “normal temperature” indicates a temperature range of approximately 0° C. to 50° C.

Here, it is preferable that the polymer-based piezoelectric composite material (piezoelectric layer 20) satisfies the following requirements.

### (i) Flexibility

For example, in a case of being gripped in a state of being loosely bent with a sense of document such as a newspaper and a magazine as a portable device, the polymer-based piezoelectric composite material is continuously subjected to large bending deformation from the outside at a comparatively slow vibration of less than or equal to a few Hz. At this time, in a case where the polymer-based piezoelectric composite material is rigid, large bending stress is generated to that extent, and a crack is generated at an interface between the polymer matrix and the piezoelectric particles, which may lead to breakage. Accordingly, the polymer-based piezoelectric composite material is required to have suitable flexibility. In addition, in a case where strain energy is diffused into the outside as heat, the stress can be relaxed. Therefore, the polymer-based piezoelectric composite material is required to have a suitably large loss tangent.

That is, the flexible polymer-based piezoelectric composite material used as an exciter is required to exhibit a behavior of being rigid with respect to a vibration of 20 Hz to 20 KHz and being flexible with respect to a vibration of less than or equal to a few Hz. In addition, the loss tangent of the polymer-based piezoelectric composite material is required to be suitably large with respect to the vibration of all frequencies of 20 kHz or less.

Furthermore, it is preferable that the spring constant can be easily adjusted by lamination in accordance with the rigidity (hardness, stiffness, and spring constant) of the mating material (vibration plate) to be attached. In that regard, as an adhesive layer 104 is thinner, the energy efficiency can be increased.

In general, a polymer solid has a viscoelasticity relaxing mechanism, and a molecular movement with a large scale is observed as a decrease (relief) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 20), the polymer-based piezoelectric composite material exhibiting a behavior of being rigid with respect to the vibration of 20 Hz to 20 KHz and being flexible with respect to the slow vibration of less than or equal to a few Hz is achieved by using, as a matrix, a polymer material having a glass transition point at normal temperature, that is, a polymer material having viscoelasticity at normal temperature. In particular, from the viewpoint that such a behavior is suitably exhibited, it is preferable that a polymer material in which the glass transition point at a frequency of 1 Hz is at normal temperature, that is, in a range of 0° C. to 50° C. is used for a matrix of the polymer-based piezoelectric composite material.

As the polymer material having a viscoelasticity at normal temperature, various known materials can be used. It is preferable that a polymer material in which the maximal value of a loss tangent Tan δ at a frequency of 1 Hz according to a dynamic viscoelasticity test at normal temperature, that is, in a range of 0° C. to 50° C. is 0.5 or more is used as the polymer material.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In the polymer material having a viscoelasticity at normal temperature, it is preferable that a storage elastic modulus (E′) at a frequency of 1 Hz according to the dynamic viscoelasticity measurement is 100 MPa or more at 0° C. and 10 MPa or less at 50° C.

In this manner, a bending moment generated in a case where the polymer-based piezoelectric composite material is slowly bent due to the external force can be reduced, and at the same time, the polymer-based piezoelectric composite material can exhibit a behavior of being rigid with respect to an acoustic vibration of 20 Hz to 20 kHz.

In addition, it is more suitable that a relative permittivity of the polymer material having a viscoelasticity at normal temperature is 10 or more at 25° C. Accordingly, in a case where a voltage is applied to the polymer-based piezoelectric composite material, a higher electric field is applied to the piezoelectric particles in the matrix, and thus a large deformation amount can be expected.

However, in consideration of ensuring favorable moisture resistance and the like, it is suitable that the relative permittivity of the polymer material is 10 or less at 25° C.

Examples of the polymer material having a viscoelasticity at normal temperature and satisfying such conditions include cyanoethylated polyvinyl alcohol (cyanoethylated PVA), polyvinyl acetate, poly(vinylidene chloride-co-acrylonitrile), a polystyrene-vinyl polyisoprene block copolymer, polyvinyl methyl ketone, and polybutyl methacrylate. In addition, as these polymer materials, a commercially available product such as Hybrar 5127 (manufactured by Kuraray Co., Ltd.) can also be suitably used. Among these, as the polymer material, a material having a cyanoethyl group is preferably used, and cyanoethylated PVA is particularly preferably used.

Among these, as the polymer material having viscoelasticity at normal temperature, it is preferable to use a polymer material having a cyanoethyl group and particularly preferable to use cyanoethylated PVA. That is, in the present invention, as the matrix 34 of the piezoelectric layer 20, it is preferable to use a polymer material containing a cyanoethyl group and particularly preferable to use cyanoethylated PVA.

In the following description, the above-described polymer materials typified by cyanoethylated PVA will also be collectively referred to as “polymer material having viscoelasticity at normal temperature”.

These polymer materials having viscoelasticity at normal temperature may be used alone or in combination (mixture) of two or more kinds thereof.

The matrix 34 using such a polymer material having a viscoelasticity at normal temperature may use a plurality of polymer materials in combination as necessary.

That is, in order to control dielectric properties, mechanical properties, or the like, other dielectric polymer materials may be added to the matrix 34 as necessary, in addition to the viscoelastic material such as cyanoethylated PVA.

Examples of the dielectric polymer material which can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidence fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among these, a polymer material having a cyanoethyl group is suitably used.

In addition, in the matrix 34 of the piezoelectric layer 20, the number of these dielectric polymer materials is not limited to one, and a plurality of kinds of dielectric polymer materials may be added.

In addition, for the purpose of controlling the glass transition point Tg, a thermoplastic resin such as a vinyl chloride resin, polyethylene, polystyrene, a methacrylic resin, polybutene, and isobutylene, and a thermosetting resin such as a phenol resin, a urea resin, a melamine resin, an alkyd resin, and mica may be added to the matrix 34 in addition to the dielectric polymer material.

Furthermore, for the purpose of improving pressure sensitive adhesiveness, a viscosity imparting agent such as rosin ester, rosin, terpene, terpene phenol, and a petroleum resin may be added.

In the matrix 34 of the piezoelectric layer 20, an addition amount of materials to be added, other than the polymer material having viscoelasticity, such as cyanoethylated PVA, is not particularly limited, but is preferably set to 30% by mass or less in terms of the proportion of the materials in the matrix 34.

In this manner, characteristics of the polymer material to be added can be exhibited without impairing the viscoelasticity relaxing mechanism in the matrix 34, so that preferred results such as an increase in permittivity, improvement of heat resistance, and improvement of adhesiveness between the piezoelectric particles 36 and the electrode layer can be obtained.

The piezoelectric layer 20 is a layer consisting of the polymer-based piezoelectric composite material containing the piezoelectric particles 36 in the matrix 34. The piezoelectric particles 36 are dispersed in the matrix 34. It is preferable that the piezoelectric particles 36 are dispersed uniformly (substantially uniform) in the matrix 34.

The piezoelectric particles 36 consist of ceramic particles having a perovskite type or wurtzite type crystal structure.

Examples of the ceramic particles constituting the piezoelectric particles 36 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

A particle diameter of the piezoelectric particles 36 is not limited, and may be suitably selected depending on the size of the piezoelectric element 50 and the applications of the piezoelectric element 50. The particle diameter of the piezoelectric particles 36 is preferably 1 to 10 μm.

By setting the particle diameter of the piezoelectric particles 36 to be within the above-described range, preferred results in terms of achieving both excellent piezoelectric characteristics and flexibility of the piezoelectric element 50 can be obtained.

The piezoelectric particles 36 in the piezoelectric layer 20 may be uniformly and regularly dispersed in the matrix 34, or may be uniformly dispersed in the matrix 34 even in a case where the piezoelectric particles 36 are irregularly dispersed in the matrix 34.

In the piezoelectric element 50, a ratio between an amount of the matrix 34 and an amount of the piezoelectric particles 36 in the piezoelectric layer 20 is not limited, and may be appropriately set according to the size and the thickness of the piezoelectric element 50 in the plane direction, the applications of the piezoelectric element 50, the characteristics required for the piezoelectric element 50, and the like.

A volume fraction of the piezoelectric particles 36 in the piezoelectric layer 20 is preferably 30% to 80%, more preferably 50% or more, and still more preferably 50% to 80%.

By setting the ratio between the amount of the matrix 34 and the amount of the piezoelectric particles 36 to be within the above-described range, preferred results in terms of achieving both of excellent piezoelectric characteristics and flexibility can be obtained.

In the piezoelectric element 50, a thickness of the piezoelectric layer 20 is not particularly limited and may be appropriately set according to the applications of the piezoelectric element 50, the number of lamination of the piezoelectric layers in the piezoelectric element 50, the characteristics required for the piezoelectric element 50, and the like.

It is advantageous that the thickness of the piezoelectric layer 20 increases large in terms of stiffness such as the strength of rigidity of a so-called sheet-like material, but the voltage (potential difference) required to stretch and contract the piezoelectric element 50 increases by the same amount.

The thickness of the piezoelectric layer 20 is preferably 10 to 300 μm, more preferably 20 to 200 μm, and still more preferably 30 to 150 μm.

By setting the thickness of the piezoelectric layer 20 to be within the above-described ranges, preferred results in terms of achieving both ensuring of the rigidity and moderate elasticity can be obtained.

In addition, it is preferable that the piezoelectric layer 20 is subjected to a polarization treatment (poling) in the thickness direction.

The first protective layer 28a and the second protective layer 28b in the piezoelectric element 50 have a function of coating the first electrode layer 24a and the second electrode layer 24b and imparting moderate rigidity and mechanical strength to the piezoelectric layer 20. That is, the piezoelectric layer 20 consisting of the matrix 34 and the piezoelectric particles 36 in the piezoelectric element 50 exhibits extremely excellent flexibility under bending deformation at a slow vibration, but may have insufficient rigidity or mechanical strength depending on the applications. As a compensation for this, the piezoelectric element 50 is provided with the first protective layer 28a and the second protective layer 28b.

The protective layer 28 is not limited, and various sheet-like materials can be used as the protective layer, and suitable examples thereof include various resin films.

Among these, from the viewpoint of excellent mechanical characteristics and heat resistance, a resin film consisting of polyethylene terephthalate (PET), polypropylene (PP), polystyrene (PS), polycarbonate (PC), polyphenylene sulfite (PPS), polymethylmethacrylate (PMMA), polyetherimide (PEI), polyimide (PI), polyethylene naphthalate (PEN), triacetyl cellulose (TAC), a cyclic olefin-based resin, and the like is suitably used.

A thickness of the protective layer 28 is not limited. In addition, the thicknesses of the first protective layer 28a and the second protective layer 28b are basically the same as each other, but may be different from each other.

Here, in a case where the rigidity of the protective layer 28 is extremely high, not only is the stretch and contraction of the piezoelectric layer 20 constrained, but also the flexibility is impaired. Therefore, it is advantageous that the thickness of the protective layer 28 decrease except for a case where the mechanical strength or excellent handleability as a sheet-like material is required.

In a case where the thickness of the protective layer 28 in the piezoelectric element 50 is two times or less the thickness of the piezoelectric layer 20, preferred results in terms of achieving both ensuring of the rigidity and moderate elasticity can be obtained.

For example, in a case where the thickness of the piezoelectric layer 20 is 50 μm and the protective layer 28 consists of PET, the thickness of the protective layer 28 is preferably 100 μm or less, more preferably 50 μm or less, and still more preferably 25 μm or less.

In the piezoelectric element 50, the first electrode layer 24a is formed between the piezoelectric layer 20 and the first protective layer 28a, and the second electrode layer 24b is formed between the piezoelectric layer 20 and the second protective layer 28b. The electrode layer 24 is provided for applying a voltage to the piezoelectric layer 20.

In the present invention, a forming material of the electrode layer 24 is not limited, and various conductors can be used as the forming material. Specific examples thereof include metals such as carbon, palladium, iron, tin, aluminum, nickel, platinum, gold, silver, copper, titanium, chromium, and molybdenum, alloys thereof, laminates and composites of these metals and alloys, and indium tin oxide. Specific examples thereof also include conductive polymers such as polyethylene dioxythiophene-polystyrene sulfonic acid (PEDOT/PPS). Among these, copper, aluminum, gold, silver, platinum, or indium tin oxide is suitably exemplified as the electrode layer 24. Among these, from the viewpoint of the conductivity, the cost, and the flexibility, copper is more preferable.

In addition, a method of forming the electrode layer 24 is not limited, and various known methods, for example, a vapor-phase deposition method (a vacuum film forming method) such as vacuum vapor deposition or sputtering, a film forming method using plating, and a method of bonding a foil formed of the materials described above can be used.

Among these, particularly from the viewpoint of ensuring the flexibility of the piezoelectric element 50, a thin film made of copper, aluminum, or the like formed by vacuum vapor deposition is suitably used as the electrode layer 24. Among these, a thin film made of copper, which is formed by vacuum vapor deposition, is particularly suitably used.

The electrode layer 24 and the protective layer 28 may be bonded to each other with an adhesive or a pressure sensitive adhesive.

A thickness of the electrode layer 24 is not limited. In addition, thicknesses of the first electrode layer 24a and the second electrode layer 24b are basically the same as each other, but may be different from each other.

Here, similarly to the above-described protective layer 28, in a case where the rigidity of the electrode layer 24 is extremely high, not only is the stretch and contraction of the piezoelectric layer 20 constrained, but also the flexibility is impaired. Therefore, it is advantageous that the thickness of the electrode layer 24 is reduced in a case where an electric resistance is not excessively high.

In the piezoelectric element 50, it is suitable that a product of the thickness of the electrode layer 24 and the Young's modulus thereof is less than a product of the thickness of the protective layer 28 and the Young's modulus thereof because the flexibility is not considerably impaired.

For example, in a case of a combination consisting of the protective layer 28 formed of PET (Young's modulus: approximately 6.2 GPa) and the electrode layer 24 consisting of copper (Young's modulus: approximately 130 GPa), assuming that the thickness of the protective layer 28 is 25 μm, the thickness of the electrode layer 24 is preferably 1.2 μm or less, more preferably 0.3 μm or less, and still more preferably 0.1 μm or less.

The common electrode layer 18 is disposed between the first piezoelectric layer 20a and the second piezoelectric layer 20b, and acts as one of electrode pairs to which a voltage is applied to the two piezoelectric layers 20.

A forming material of the common electrode layer 18 is as described above.

In addition, a metal foil may be used for the common electrode layer 18. Alternatively, a thinner common electrode layer 18 can be obtained by producing a plating layer (for example, copper plating) by a plating treatment on a metal foil as a base, and then peeling off the base. In addition, as the common electrode layer 18, it is also preferable to use a precipitated ultra-thin copper foil (MicroThin manufactured by MITSUI MINING & SMELTING CO., LTD.) in which a peeling layer is provided on a surface of the copper foil.

As described above, the thickness of the common electrode layer 18 is preferably 10 μm or less, more preferably 0.1 μm to 10 μm, still more preferably 0.3 μm to 5 μm, and particularly preferably 1 μm to 2 μm.

As described above, the piezoelectric element 50 has a configuration in which the common electrode layer 18 is sandwiched between the two piezoelectric layers 20 which are formed by dispersing the piezoelectric particles 36 in the matrix 34 containing a polymer material, the laminate is sandwiched between the first electrode layer 24a and the second electrode layer 24b, and the laminate is further sandwiched between the first protective layer 28a and the second protective layer 28b.

In such a piezoelectric element 50, it is preferable that the maximal value of the loss tangent (Tan δ) at a frequency of 1 Hz according to the dynamic viscoelasticity measurement is present at normal temperature, and it is more preferable that the maximal value at which the loss tangent is 0.1 or more is present at normal temperature.

In this manner, even in a case where the piezoelectric element 50 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In the piezoelectric element 50, it is preferable that the storage elastic modulus (E′) at a frequency of 1 Hz according to the dynamic viscoelasticity measurement is 10 to 30 GPa at 0° C. and 1 to 10 GPa at 50° C. The same applies to the conditions for the piezoelectric layer 20.

In such a manner, the piezoelectric element 50 may have large frequency dispersion in the storage elastic modulus (E′) at normal temperature. That is, the piezoelectric film 10 can exhibit a behavior of being rigid with respect to the vibration of 20 Hz to 20 kHz and being flexible with respect to the vibration of less than or equal to a few Hz.

In addition, in the present invention, the storage elastic modulus (Young's modulus) and the loss tangent of the piezoelectric element 50, the piezoelectric layer 20, and the like may be measured by a known method. As an example, the measurement may be performed using a dynamic viscoelasticity measuring device DMS6100 (manufactured by SII Nanotechnology Inc.).

Examples of measurement conditions include conditions with a measurement frequency of 0.1 Hz to 20 Hz (0.1 Hz, 0.2 Hz, 0.5 Hz, 1 Hz, 2 Hz, 5 Hz, 10 Hz, and 20 Hz), a measurement temperature of −50° C. to 150° C., a temperature rising rate of 2° C./min (in a nitrogen atmosphere), a sample size of 40 mm×10 mm (including the clamped region), and a chuck-to-chuck distance of 20 mm.

In the piezoelectric element 50, a power supply (external power supply) which applies a driving voltage for stretching and contracting the piezoelectric layer 20, that is, supplies a driving power is connected to the electrode layer 24 and the common electrode layer 18.

The power supply is not limited, and may be a direct-current power supply or an alternating-current power supply. In addition, the driving voltage may be appropriately set to a driving voltage capable of appropriately driving the piezoelectric element 50 according to the thickness, the forming material, and the like of the piezoelectric layer 20 in the piezoelectric element 50.

A method of leading out the electrode from the electrode layer 24 is not limited, and various known methods can be used.

Examples thereof include a method of connecting a conductor such as a copper foil to the electrode layer 24 and leading-out the electrode to the outside, and a method of forming through-holes in the protective layer 28 with a laser or the like, filling the through-holes with a conductive material, and leading-out the electrode to the outside. Alternatively, as in the examples shown in FIG. 1 and the like, the electrode layer 24 may have a configuration in which the lead-out portion 25 which protrudes to the outside of the region where the respective layers are laminated in the plane direction is provided.

Examples of a suitable method of leading out the electrodes include the method described in JP2014-209724A and the method described in JP2016-015354A.

Alternatively, as shown in FIG. 20 described later, the electrode may be led out using a conductive member which is electrically connected to the common electrode layer 18 or the electrode layer in a hole portion which penetrates through the one protective layer side until the common electrode layer 18 or the other electrode layer is exposed.

As shown in FIG. 1, the piezoelectric element 50 according to the embodiment of the present invention is used as an exciter by being bonded to the vibration plate 102, and constitutes the electroacoustic transducer 100.

As a preferred aspect, the vibration plate 102 has flexibility. In the present invention, the expression of “having flexibility” is synonymous with having flexibility in the general interpretation, and indicates being capable of bending and being flexible, specifically, being capable of bending and stretching without causing breakage and damage.

The vibration plate 102 is not limited as long as the vibration plate preferably has flexibility, and various sheet-like materials (plate-like material and film) can be used.

Examples thereof include resin films made of polyethylene terephthalate (PET), polypropylene (PP), polystyrene (PS), polycarbonate (PC), polyphenylene sulfide (PPS), polymethylmethacrylate (PMMA), and polyetherimide (PEI), polyimide (PI), polyethylene naphthalate (PEN), triacetyl cellulose (TAC), cyclic olefin-based resins, or the like; foamed plastics made of foamed polystyrene, foamed styrene, formed polyethylene, or the like; and various kinds of corrugated cardboard materials obtained by bonding other paperboards to one or both surfaces of a corrugated paperboard.

In addition, in the electroacoustic transducer 100, various display devices such as an organic electro-luminescence (organic light emitting diode (OLED)) display, a liquid crystal display, a micro light emitting diode (LED) display, and an inorganic electroluminescence display can also be suitably used as the vibration plate 102 as long as they have flexibility.

In the electroacoustic transducer 100, the vibration plate 102 and the piezoelectric element 50 are bonded to each other through the adhesive layer 104.

Various known layers can be used as the adhesive layer (bonding layer) 104 as long as the vibration plate 102 and the piezoelectric element 50 can be bonded to each other.

Therefore, the adhesive layer 104 may be a layer formed of an adhesive which has fluidity in a case of bonding and then is to be a solid, a layer formed of a pressure sensitive adhesive which is a gel-like (rubber-like) soft solid in a case of bonding and the gel-like state does not change thereafter, or a layer formed of a material having characteristics of both the adhesive and the pressure sensitive adhesive.

Here, in the electroacoustic transducer 100, the piezoelectric element 50 stretches and contracts to bend and vibrate the vibration plate 102, thereby generating a sound. Therefore, in the electroacoustic transducer 100, it is preferable that the stretch and contraction of the piezoelectric element 50 is directly transmitted to the vibration plate 102. In a case where a substance having viscosity, which relieves vibration, is present between the vibration plate 102 and the piezoelectric element 50, efficiency of transmitting the stretching and contracting energy of the piezoelectric element 50 to the vibration plate 102 is lowered, and driving efficiency of the electroacoustic transducer 100 is also decreased. On the other hand, in a case where the adhesive layer 104 for bonding the vibration plate 102 and the piezoelectric element 50 to each other is too hard, the piezoelectric element 50 is restrained, and the piezoelectric element 50 may not be sufficiently stretched and contracted. Therefore, it is desirable that the adhesive layer 104 for bonding the vibration plate 102 and the piezoelectric element 50 to each other has an appropriate hardness.

In consideration of this point, it is preferable that the adhesive layer 104 is an adhesive layer consisting of an adhesive from which a solid and hard adhesive layer 104 is obtained, rather than a pressure sensitive adhesive layer consisting of a pressure sensitive adhesive. Specific examples of a more preferred adhesive layer 104 include a bonding layer consisting of a thermoplastic type adhesive such as an ethylene vinyl acetate resin-based adhesive, a polyester-based adhesive, and a styrene-butadiene rubber (SBR)-based adhesive.

The adhesion, unlike pressure sensitive adhesion, is useful in a case where a high adhesion temperature is required. In addition, the thermoplastic type adhesive has “comparatively low temperature, short time, and strong adhesion”, which is suitable.

From the above-described viewpoint, a Young's modulus of the adhesive layer is preferably 0.1 GPa to 10 GPa, more preferably 0.3 GPa to 5 GPa, and still more preferably 0.5 GPa to 3 GPa.

A thickness of the adhesive layer 104 is not limited, and a thickness at which sufficient bonding strength (adhesive force or pressure sensitive adhesive force) can be obtained may be appropriately set depending on the material of the adhesive layer 104.

Here, in the electroacoustic transducer 100, as the adhesive layer 104 is thinner, the effect of transmitting the stretching and contracting energy (vibration energy) of the piezoelectric element 50 to the vibration plate 102 is higher, and the energy efficiency is higher. In addition, in a case where the adhesive layer 104 is thick and has high rigidity, there is a possibility that the stretch and contraction of the piezoelectric element 50 may be constrained.

In consideration of this point, it is preferable that the adhesive layer 104 is thin. Specifically, the thickness of the adhesive layer 104 is preferably 0.1 to 50 μm, more preferably 0.1 to 30 μm, and still more preferably 0.1 to 10 μm in terms of thickness after bonding.

In the electroacoustic transducer 100, the adhesive layer 104 is provided as a preferred aspect, and is not an essential constituent element.

Therefore, the electroacoustic transducer 100 may not include the adhesive layer 104, and the vibration plate 102 may be fixed to the piezoelectric element 50 using a known compression-bonding unit, fastening unit, fixing unit, or the like. For example, in a case where a shape of the piezoelectric element 50 is a rectangular shape in a plan view, the electroacoustic transducer may be configured by fastening four corners with members such as bolts and nuts, or the electroacoustic transducer may be configured by fastening the four corners and a center portion with members such as bolts and nuts.

However, in such a case, in a case where the driving voltage is applied from the power supply, the piezoelectric element 50 stretches and contracts independently of the vibration plate 102, and in some cases, only the piezoelectric element 50 bends, and the stretch and contraction of the piezoelectric element 50 is not transmitted to the vibration plate 102. As described above, in a case where the piezoelectric element 50 stretches and contracts independently of the vibration plate 102, the vibration efficiency of the vibration plate 102 due to the piezoelectric element 50 decreases. As a result, the vibration plate 102 may not be sufficiently vibrated.

In consideration of this point, it is preferable that the vibration plate 102 and the piezoelectric element 50 are bonded to each other with the adhesive layer 104 as shown in FIG. 1.

Here, as described above, the piezoelectric layer 20 contains the piezoelectric particles 36 in the matrix 34.

In a case where a voltage is applied to the electrode layer 24 and the common electrode layer 18 of the piezoelectric element 50 including such a piezoelectric layer 20, the piezoelectric particles 36 stretch and contract in the polarization direction according to the applied voltage. As a result, the piezoelectric element 50 (piezoelectric layer 20) contracts in the thickness direction. At the same time, the piezoelectric element 50 stretches and contracts in the in-plane direction due to a Poisson's ratio. A degree of stretch and contraction is approximately 0.01% to 0.1%.

As described above, the thickness of the piezoelectric layer 20 is preferably approximately 10 to 300 μm. Accordingly, the degree of stretch and contraction in the thickness direction is as extremely small as approximately 0.3 μm at the maximum.

On the contrary, the piezoelectric element 50, that is, the piezoelectric layer 20 has a size much larger than the thickness in a plane direction. Therefore, for example, in a case where a length of the piezoelectric element 50 is 20 cm, the piezoelectric element 50 stretches and contracts by a maximum of approximately 0.2 mm by the application of the voltage.

The vibration plate 102 is bonded to the piezoelectric element 50 with the adhesive layer 104. Therefore, the vibration plate 102 is bent by the stretch and contraction of the piezoelectric element 50, and as a result, the vibration plate 102 vibrates in the thickness direction.

The vibration plate 102 generates a sound using the vibration in the thickness direction. That is, the vibration plate 102 vibrates according to the magnitude of the voltage (driving voltage) applied to the piezoelectric element 50, and generates a sound according to the driving voltage applied to the piezoelectric element 50.

In addition, the sound pressure level can be improved by adjusting the mass of the piezoelectric element 50 in accordance with a spring constant of the vibration plate 102. In a case where the mass of the piezoelectric element 50 is large, the vibration plate 102 is bent, and thus there is a possibility that the vibration of the vibration plate 102 during driving is suppressed. On the other hand, in a case where the mass of the piezoelectric element 50 is small, the resonance frequency is high, and the vibration of the vibration plate 102 at a low frequency may be suppressed. In consideration of these points, it is preferable that the mass of the piezoelectric element 50 is appropriately adjusted according to the spring constant of the vibration plate 102.

Next, an example of the method of manufacturing the piezoelectric element 50a shown in FIG. 1 will be described with reference to FIGS. 6 to 9.

First, as shown in FIG. 6, a sheet-like material in which the electrode layer 24 has been formed on a surface of the protective layer 28 is prepared.

The sheet-like material may be produced by forming a copper thin film or the like as the electrode layer 24 on the surface of the protective layer 28 using vacuum vapor deposition, sputtering, plating, or the like. Alternatively, a commercially available product in which a copper thin film or the like is formed on a protective layer may be used as the sheet-like material.

In a case where the protective layer is extremely thin and thus the handleability is degraded, the protective layer with a separator (temporary support) may be used as necessary. PET having a thickness of 25 to 100 μm, or the like can be used as the separator. The separator may be removed after thermal compression bonding of the electrode layer and the protective layer.

Next, as shown in FIG. 6, the electrode layer 24 of the sheet-like material is coated with a coating material (coating composition) forming the piezoelectric layer 20, and the coating material is cured to form the piezoelectric layer 20. In this manner, the sheet-like material and the piezoelectric layer 20 are laminated.

The piezoelectric layer 20 can be formed by various methods depending on the forming material of the piezoelectric layer 20.

As an example, first, the coating material is prepared by dissolving the above-described polymer material such as cyanoethylated PVA in an organic solvent, adding the piezoelectric particles 36 such as PZT particles thereto, and stirring the solution.

The organic solvent is not limited, and various organic solvents such as dimethylformamide (DMF), methyl ethyl ketone (MEK), and cyclohexanone can be used.

In a case where the sheet-like material is prepared and the coating material is prepared, the coating material is cast (applied) onto the sheet-like material, and the organic solvent is evaporated and dried. In this manner, as shown in FIG. 6, the laminate in which the electrode layer 24 is provided on the protective layer 28 and the piezoelectric layer 20 is laminated on the electrode layer 24 is produced.

A casting method of the coating material is not limited, and all known methods (coating devices) such as a bar coater, a slide coater, and a doctor knife can be used.

Alternatively, in a case where the polymer material is a material that can be heated and melted, the laminate as shown in FIG. 6 may be produced by heating and melting the polymer material to produce a melt obtained by adding the piezoelectric particles 36 to the melted material, extruding the melt on the sheet-like material in a sheet shape by carrying out extrusion molding or the like, and cooling the laminate.

In addition, the electrode layer 24 and the piezoelectric layer 20 may be bonded to each other with an adhesive or a pressure sensitive adhesive. As the adhesive for bonding the electrode layer 24 and the piezoelectric layer 20 to each other, a polymer material obtained by removing the piezoelectric particles 36 from the piezoelectric layer 20, that is, the same material as the matrix 34 can be suitably used.

As described above, in the piezoelectric layer 20 a polymer piezoelectric material such as PVDF may be added to the matrix 34, in addition to the polymer material having viscoelasticity at normal temperature.

In a case where the polymer piezoelectric material is added to the matrix 34, the polymer piezoelectric material to be added to the above-described coating material may be dissolved. Alternatively, the polymer piezoelectric material to be added may be added to the heated and melted polymer material having viscoelasticity at normal temperature so that the polymer piezoelectric material is heated and melted.

After forming the piezoelectric layer 20, a calender treatment may be performed as necessary. The calender treatment may be performed once or a plurality of times.

As is well known, the calender treatment is a treatment in which the surface to be treated is pressed while being heated by a heating press, a heating roller, or the like to flatten the surface.

Next, the piezoelectric layer 20 of the laminate including the electrode layer 24 on the protective layer 28 and including the piezoelectric layer 20 formed on the electrode layer 24 is subjected to a polarization treatment (poling). The polarization treatment of the piezoelectric layer 20 may be performed before the calender treatment, but it is preferable that the polarization treatment is performed after the calender treatment.

A method of performing the polarization treatment on the piezoelectric layer 20 is not limited, and a known method can be used. For example, electric field poling in which a DC electric field is directly applied to a target to be subjected to the polarization treatment is exemplified. In a case of performing the electric field poling, as shown in FIG. 9 described later, the common electrode layer 18 may be laminated, the laminate of the piezoelectric layer 20, the electrode layer 24, and the protective layer 28 may be folded, and then the electric field poling treatment may be performed using the electrode layer 24 and the common electrode layer 18.

In addition, in the piezoelectric element 50 according to the embodiment of the present invention, it is preferable that the polarization treatment is performed in the thickness direction instead of the plane direction of the piezoelectric layer 20.

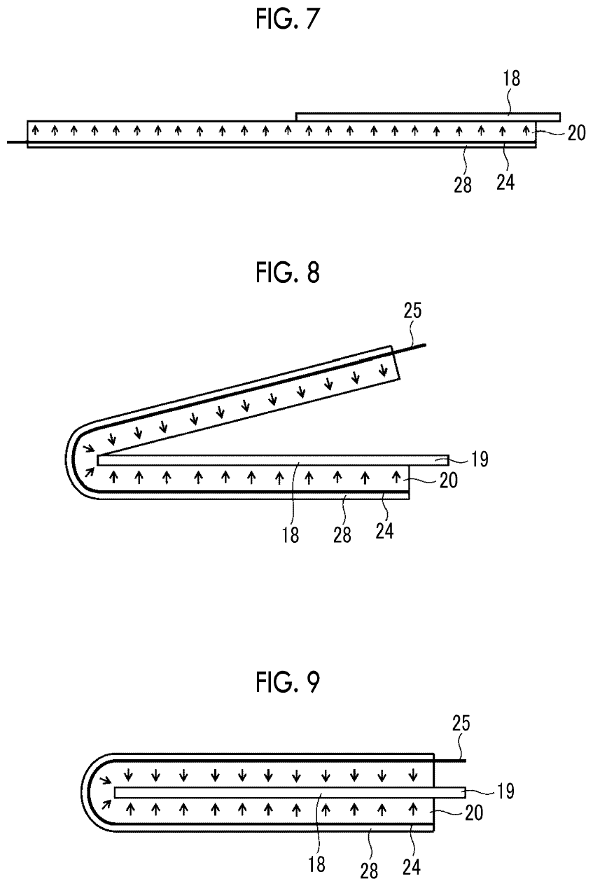

Next, as shown in FIG. 7, the common electrode layer 18 is laminated on the laminate on the piezoelectric layer 20 side. In this case, as shown in FIG. 7, the common electrode layer 18 is laminated to cover approximately half of the piezoelectric layer 20.

The common electrode layer 18 may be laminated on the piezoelectric layer 20 using, for example, a commercially available metal foil. Alternatively, for example, a copper foil which is peelably provided on a temporary support such as a resin film, a copper foil in which a peeling layer is provided on a surface of a copper foil and a precipitated ultra-thin copper foil (MicroThin manufactured by MITSUI MINING & SMELTING CO., LTD.), or the like may be used to laminate the copper foil (ultra-thin copper foil) on the piezoelectric layer 20, and then the temporary support may be peeled off to form the laminate.

In this case, a configuration in which the copper foil (ultra-thin copper foil) and the piezoelectric layer 20 are temporarily adhered to each other at a low temperature by thermal compression bonding or the like, and then the temporary support is peeled off may be adopted.

Next, as shown in FIG. 8, in the laminate of the piezoelectric layer 20, the electrode layer 24, and the protective layer 28, a region where the common electrode layer 18 is not laminated is folded back to the common electrode layer 18 side, and a configuration in which the common electrode layer 18 is interposed between the laminate of the piezoelectric layer 20, the electrode layer 24, and the protective layer 28, as shown in FIG. 9, is adopted.

After the common electrode layer 18 is interposed between the piezoelectric layer 20, the electrode layer 24, and the protective layer 28 to form a laminate, the laminate and the common electrode layer 18 are thermal compression-bonded using a heating press device, a heating roller, or the like to bond (mainly bond) the laminate and the common electrode layer 18 to each other, thereby producing a piezoelectric element 50 as shown in FIG. 9. The thermal compression bonding at this time is preferably performed at a temperature of 100° C. or higher. In addition, in a case where the protective layer is attached with a separator, it is preferable to peel off the separator after the thermal compression bonding, but a timing of peeling off the separator is not limited thereto.

The common electrode layer 18 and the piezoelectric layer 20 may be bonded to each other using an adhesive, and may be further pressed to produce the piezoelectric element 50.

The adhesive for bonding the common electrode layer 18 and the piezoelectric layer 20 to each other may be an adhesive or a pressure sensitive adhesive. In addition, the same material as the polymer material obtained by removing the piezoelectric particles 36 from the piezoelectric layer 20, that is, the matrix 34 can also be suitably used as the adhesive. The adhesive layer may be provided on both the first electrode layer 24a side and the second electrode layer 24b side, or may be provided only on one of the first electrode layer 24a side or the second electrode layer 24b side.

The produced piezoelectric element 50 may be cut into a desired shape according to various applications.

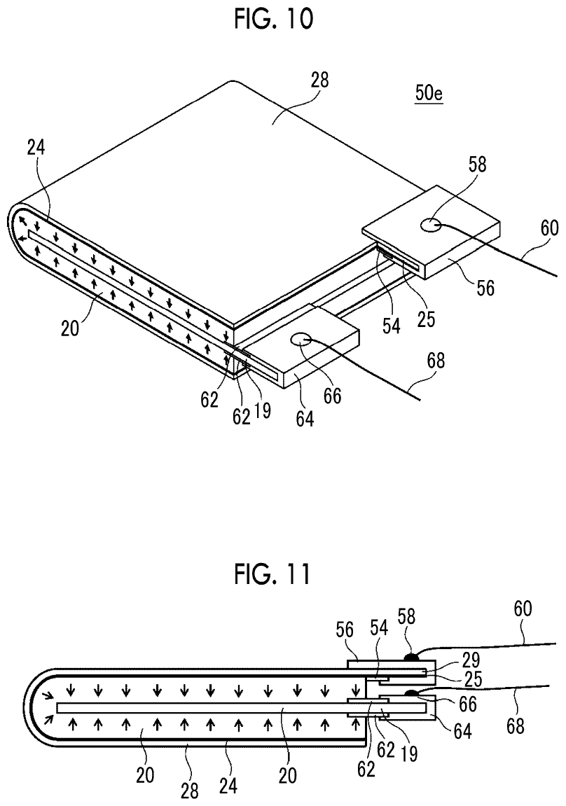

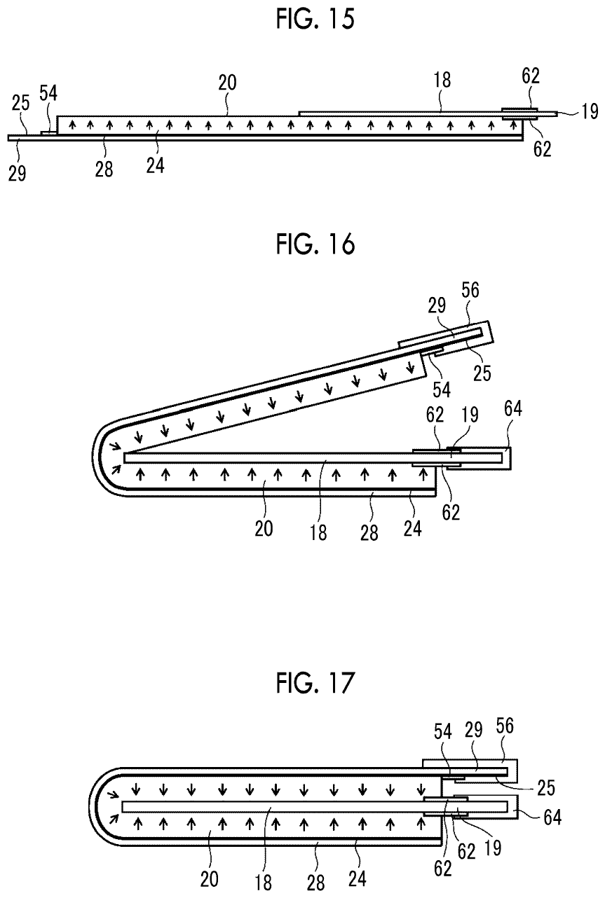

Hereinafter, an example of a lead-out method of the electrode in the piezoelectric element according to the embodiment of the present invention will be described with reference to FIGS. 10 to 17.

FIG. 10 is a perspective view schematically showing another example of the piezoelectric element according to the embodiment of the present invention. FIG. 11 is a side view of the piezoelectric element shown in FIG. 10.

A piezoelectric element 50e shown in FIGS. 10 and 11 basically has the same configuration as the piezoelectric element 50a shown in FIG. 1, except that the piezoelectric element 50e includes an insulating sheet 54, a conductive sheet 56, a solder 58, a lead wire (wiring line) 60, an insulating sheet 62, a conductive sheet 64, a solder 66, a lead wire (wiring line) 68, and an insulating sheet 70.

The piezoelectric element 50e shown in FIGS. 10 and 11 has, on one end part side in a width direction orthogonal to a folding-back direction as viewed in a direction perpendicular to the main surface, a lead-out portion 25 which is led out from the electrode layer 24 to the outside of a region where the respective layers are laminated, and a protruding portion 29 which is led out from the protective layer 28 to the outside in the same manner as the lead-out portion 25. The insulating sheet 54 is laminated on a region of a surface of the lead-out portion 25 on a side opposite to the protruding portion 29, in the vicinity of the piezoelectric layer 20. In addition, the conductive sheet 56 is laminated by being folded back to cover from the surface of the lead-out portion 25 opposite to the surface of the protruding portion 29 to the surface of the protruding portion 29 opposite to the surface of the lead-out portion 25, except for at least a part of the insulating sheet 54. A part of the surface of the conductive sheet 56 is connected to the lead wire 60 by the solder 58.

In addition, the piezoelectric element 50e has, on the other end part side in the width direction orthogonal to the folding-back direction as viewed in a direction perpendicular to the main surface, a lead-out portion 19 which protrudes to the outside of the region where the respective layers are laminated in the common electrode layer 18. Each insulating sheet 62 is disposed in the vicinity of the piezoelectric layer 20 on both surfaces of the lead-out portion 19. In the illustrated example, the insulating sheet 62 is disposed such that a part thereof is interposed between the common electrode layer 18 and the piezoelectric layer 20. In addition, the conductive sheet 64 is laminated by being folded back to cover from one surface of the lead-out portion 19 to the other surface, except for at least a part of the insulating sheet 62. A part of the surface of the conductive sheet 64 is connected to the lead wire 68 by the solder 66.

Since the common electrode layer 18 and the electrode layer 24 are extremely thin, it is difficult to directly solder the lead-out portions (19 and 25) thereof. Therefore, it is easy to perform soldering by attaching the conductive sheets 56 and 64 to the lead-out portions 19 and 25 of the common electrode layer 18 and the electrode layer 24, respectively. On the other hand, in a case where the conductive sheets 56 and 64 are attached to the lead-out portions 19 and 25, the lead-out portions 19 and 25 may hang down due to their weight; and the lead-out portion 19 may come into contact with the end part of the electrode layer 24 and the lead-out portion 25 may come into contact with the end part of the common electrode layer 18, or the lead-out portion 19 and the lead-out portion 25 may be close to each other, which may cause dielectric breakdown and discharge. On the other hand, by disposing the insulating sheets 62 in the vicinity of the piezoelectric layer 20 on both surfaces of the lead-out portion 19 (in a root part of the lead-out portion 19) and disposing the insulating sheets 54 in the vicinity of the piezoelectric layer 20 of the lead-out portion 25 (in a root part of the lead-out portion 25), the mechanical strength is imparted, and thus the lead-out portions 19 and 25 can be prevented from hang down even in a case where the conductive sheets 56 and 64 are attached.

In addition, in a case where the end side of the electrode layer 24 is not smooth and is present in a form in which a burr generated during cutting protrudes to the outside, electric field concentration is likely to occur between the lead-out portion 19 of the common electrode layer 18, and there is a risk of dielectric breakdown and spark discharge. By disposing the insulating sheet in the root part of the common electrode layer 18, it is possible to prevent the dielectric breakdown between the burr at the end side of the electrode layer 24.

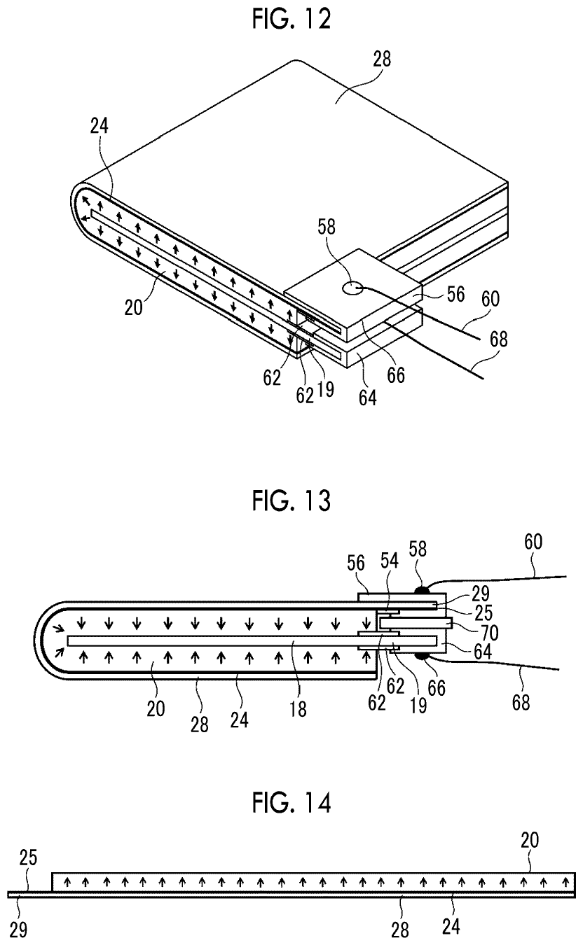

Here, in the example shown in FIG. 10, the configuration in which the lead-out portion 25 of the electrode layer 24 and the lead-out portion 19 of the common electrode layer 18 are formed at positions which do not overlap with each other in a case of being viewed from a direction perpendicular to the main surface of the piezoelectric element (hereinafter, also referred to as “in a plane direction”) is adopted, but the present invention is not limited thereto. FIG. 12 shows a perspective view schematically showing another example of the piezoelectric element according to the embodiment of the present invention. FIG. 13 shows a side view of FIG. 12.

A piezoelectric element 50f shown in FIGS. 12 and 13 has the same configuration as the piezoelectric element 50c shown in FIG. 10, except that the positions of the lead-out portion 25 of the electrode layer 24, and the insulating sheet 54, the conductive sheet 56, the solder 58, and the lead wire 60 arranged in the lead-out portion 25 are different, and an insulating sheet 70 is provided.

In the piezoelectric element 50f, the lead-out portion 25 of the electrode layer 24 and the lead-out portion 19 of the common electrode layer 18 are arranged at overlapping positions in a case of being viewed from a direction perpendicular to the main surface of the piezoelectric element. In such a configuration, the conductive sheet 56 disposed in the lead-out portion 25 and the conductive sheet 64 disposed in the lead-out portion 19 are likely to come into contact with each other, and there is a risk of dielectric breakdown because the distance therebetween is short.

On the other hand, as shown in FIG. 13, by disposing the insulating sheet 70 between the conductive sheet 56 disposed in the lead-out portion 25 and the conductive sheet 64 disposed in the lead-out portion 19, it is possible to prevent the conductive sheet 56 and the conductive sheet 64 from coming into contact with each other and to prevent the dielectric breakdown. In addition, in a case where a double-sided tape having insulating properties is used as the insulating sheet 70, the lead-out portion 25 and the lead-out portion 19 are supported by each other, so that the hanging down of the lead-out portions can be suppressed.

The conductive sheets 56 and 64 are sheet-like materials formed of a conductive metal material such as a copper foil. In addition, the conductive sheets 56 and 64 may have a conductive pressure-sensitive adhesive layer, and may be adhered to the lead-out portion 19 and the lead-out portion 25 through the pressure-sensitive adhesive layer. Suitable examples of the material of the conductive sheets 56 and 64 include copper, aluminum, gold, and silver.

A thickness of the conductive sheets 56 and 64 is preferably 1 μm to 25 μm and more preferably 3 μm to 12 μm.

The insulating sheets 54, 62, and 70 are sheet-like materials formed of a material having insulating properties, such as a tape made of polyimide. Alternatively, the insulating sheets 54, 62, and 70 may be an insulating layer formed by applying and curing a liquid insulating material. Suitable examples of the materials of the insulating sheets 54, 62, and 70 include polyimide (PI), polyethylene terephthalate (PET), polyethylene naphthalate (PEN), and polypropylene (PP). In addition, as described above, the insulating sheet 70 may be a double-sided tape having insulating properties.

A thickness of the insulating sheets 54 and 62 is preferably 1 μm to 25 μm and more preferably 3 μm to 12 μm.

Next, an example of a production method of the piezoelectric element shown in FIG. 10 will be described with reference to FIGS. 14 to 17.

First, similarly to FIG. 6 described above, a sheet-like material in which the electrode layer 24 is formed on the surface of the protective layer 28 is prepared, the electrode layer 24 of the sheet-like material is coated with a coating material to be the piezoelectric layer 20, and the coating material is cured to form the piezoelectric layer 20. In addition, a calender treatment, a polarization treatment, or the like may be performed in this state.

Next, as shown in FIG. 14, the piezoelectric layer 20 formed on the region of the electrode layer 24, which is to be the lead-out portion 25, is removed using a solvent such as acetone to expose the electrode layer 24. The insulating sheet 54 is laminated on the root part of the exposed electrode layer 24.

In addition, as shown in FIG. 14, the common electrode layer 18 is disposed on the piezoelectric layer 20 of the region on the side opposite to the end part of the region to be the lead-out portion 25. The common electrode layer 18 is laminated so as to cover substantially half of the piezoelectric layer 20. In addition, the common electrode layer 18 is laminated such that a part thereof to be the lead-out portion 19 protrudes outward from the piezoelectric layer 20. In addition, in a case where the common electrode layer 18 is laminated on the piezoelectric layer 20, the insulating sheet 62 is disposed on both surfaces of the root part to be the lead-out portion 19 of the common electrode layer 18.

In addition, as shown in FIG. 10, in a case where the lead-out portion 25 is formed at one end part in the width direction, the electrode layer 24 and the protective layer 28 may be cut into such that the lead-out portion 25 has a desired shape, at any of timings before the piezoelectric layer 20 is formed, after the piezoelectric layer 20 is formed, or after a part of the piezoelectric layer 20 is removed. Similarly, in a case where the lead-out portion 19 is formed at one end part in the width direction, the common electrode layer 18 may be cut into such that the lead-out portion 19 has a desired shape, before or after the common electrode layer 18 is laminated on the piezoelectric layer 20.

Next, as shown in FIG. 16, the conductive sheet 56 is laminated on the lead-out portion 25 and the conductive sheet 64 is laminated on the lead-out portion 19, and in the laminate of the piezoelectric layer 20, the electrode layer 24, and the protective layer 28, the region where the common electrode layer 18 is not laminated is folded back to the common electrode layer 18, so that the common electrode layer 18 is interposed between the laminate of the piezoelectric layer 20, the electrode layer 24, and the protective layer 28.

After the common electrode layer 18 is interposed between the piezoelectric layer 20, the electrode layer 24, and the protective layer 28 to form a laminate, the laminate and the common electrode layer 18 are thermal compression-bonded using a heating press device, a heating roller, or the like to bond the laminate and the common electrode layer 18 to each other, thereby producing a piezoelectric element 50 as shown in FIG. 17.

In addition, each of the conductive sheet 56 and the conductive sheet 64 is connected to the lead wire (wiring line) by the solder (see FIG. 11).

Another example of a method of leading out the electrode in the present invention will be described with reference to FIG. 20.

FIG. 20 is an enlarged cross-sectional view of a part of the piezoelectric element according to the embodiment of the present invention.

A piezoelectric element shown in FIG. 20 includes a common electrode layer 18, a first piezoelectric layer 20a provided in contact with one main surface (upper surface in FIG. 20) of the common electrode layer 18, a first electrode layer 24a provided in contact with a surface of the first piezoelectric layer 20a on a side opposite to the common electrode layer 18, a first protective layer 28a provided in contact with a surface of the first electrode layer 24a on a side opposite to the first piezoelectric layer 20a, a second piezoelectric layer 20b provided in contact with the other main surface (lower surface in FIG. 20) of the common electrode layer 18, a second electrode layer 24b provided in contact with a surface of the second piezoelectric layer 20b on a side opposite to the common electrode layer 18, a second protective layer 28b provided in contact with a surface of the second electrode layer 24b on a side opposite to the second piezoelectric layer 20b, a conductive member 40, an insulating layer 42, a second conductive member 44, and an insulating layer 46.

In the piezoelectric element shown in FIG. 20, the same reference numeral is attached to the same part as that in the piezoelectric element shown in FIG. 1, and different parts will be mainly described below.

In the piezoelectric element shown in FIG. 20, a hole portion penetrating the first protective layer 28a, the first electrode layer 24a, and the first piezoelectric layer 20a is formed. A part of the common electrode layer 18 is exposed through the hole portion. The conductive member 40 is disposed in the hole portion.

In the hole portion, the conductive member 40 is in direct contact with the common electrode layer 18 and is electrically connected thereto. A configuration in which the conductive member 40 and the common electrode layer 18 are in direct contact with each other is not limited, and the conductive member 40 and the common electrode layer 18 may be indirectly connected to each other as long as they are electrically connected to each other.

In addition, as shown in FIG. 20, the conductive member 40 extends from a position in contact with the common electrode layer 18 to the first protective layer 28a side along a side surface of the hole portion, and is formed to extend along a surface of the first protective layer 28a (surface opposite to a surface in contact with the first electrode layer 24a) to cover a part of the first protective layer 28a.

With this configuration, the common electrode layer 18 is led out to the surface of the first protective layer 28a.

The insulating layer 42 is a layer for preventing the common electrode layer 18 and the conductive member 40 from being short-circuited at the side surface of the hole portion, by disposing the insulating layer 42 between an edge surface of the first electrode layer 24a, which is exposed at the side surface of the hole portion, and the common electrode layer 40, so that the common electrode layer 40 and the first electrode layer 24a are not electrically connected to each other.

In the example shown in FIG. 20, the insulating layer 42 is formed up to the hole portion in the part between the common electrode layer 18 and the first piezoelectric layer 20a, and is formed to extend to the surface of the first protective layer 28a along the side surface of the hole portion and to extend along the surface of the first protective layer 28a to cover a part of the first protective layer 28a. That is, the insulating layer 42 has a cross section formed in a substantially U shape.

In the piezoelectric element shown in FIG. 20, a second hole portion penetrating the first protective layer 28a, the first electrode layer 24a, the first piezoelectric layer 20a, and the second piezoelectric layer 20b is formed. A part of the second electrode layer 24b is exposed through the second hole portion. The second conductive member 44 is disposed in the second hole portion. As shown in FIG. 20, the common electrode layer 18 is not formed at a position where the second hole portion is formed.

In the second hole portion, the second conductive member 44 is in direct contact with the second electrode layer 24b, and is electrically connected thereto. A configuration in which the second conductive member 44 and the second electrode layer 24b are in direct contact with each other is not limited, and the second conductive member 44 and the second electrode layer 24b may be indirectly connected to each other as long as they are electrically connected to each other.

In addition, as shown in FIG. 20, the second conductive member 44 extends from a position in contact with the second electrode layer 24b to the first protective layer 28a side along a side surface of the second hole portion, and is formed to extend along a surface of the first protective layer 28a (surface opposite to a surface in contact with the first electrode layer 24a) to cover a part of the first protective layer 28a.

With this configuration, the second electrode layer 24b is led out to the surface of the first protective layer 28a.

The insulating layer 42 is a layer for preventing the second conductive member 44 and the first electrode layer 24a from being electrically connected to each other at the side surface of the second hole portion, by disposing the insulating layer 42 between an edge surface of the first electrode layer 24a, which is exposed at the side surface of the second hole portion, and the second conductive member 44.

In the example shown in FIG. 20, the insulating layer 46 is formed between the first electrode layer 24a exposed at the side surface of the second hole portion and the conductive member 44, and is formed to extend to the surface of the first protective layer 28a along the side surface of the second hole portion and to extend along the surface of the first protective layer 28a to cover a part of the first protective layer 28a. That is, the insulating layer 46 has a cross section formed in a substantially L shape.

Since the first electrode layer 24a and the second electrode layer 24b are basically connected to the electrode having the same polarity, the first electrode layer 24a and the second conductive member 44 connected to the second electrode layer 24b may be in electrical contact with each other. However, since the first electrode layer 24a is extremely thin and an area of the edge surface exposed at the side surface of the second hole portion is extremely small, the connection with the second conductive member 44 is likely to be unstable, and heat is likely to be generated. Therefore, by disposing the insulating layer 46 between the edge surface of the first electrode layer 24a and the second conductive member 44, it is possible to prevent poor connection and suppress heat generation.

In this way, the electrode may be led out as the configuration including the hole portion which penetrates the first protective layer, the first electrode layer, and the first piezoelectric layer to expose the common electrode layer and including the conductive member which is electrically connected to the common electrode layer at the hole portion and provided to cover a part of the surface of the first protective layer, and/or as the configuration including the second hole portion which exposes, from the first protective layer side, an electrode layer adjacent to the other side (second electrode layer) and including the second conductive member which is electrically connected to the second electrode layer at the second hole portion and provided to cover a part of the surface of the first protective layer. Hereinafter, such configurations will also be referred to as a through-hole electrode structure.

By leading out the common electrode layer and the electrode layer with the through-hole electrode structure, it is possible to connect the piezoelectric element to the wiring line on one surface of the piezoelectric element, and it is possible to facilitate the connection to the wiring line. For example, in a case where the piezoelectric element is bonded to the vibration plate, the common electrode layer and the electrode layer are led out to a surface of the piezoelectric element opposite to a surface bonded to the vibration plate, so that the piezoelectric element can be easily connected to the wiring line.

In addition, since the through-hole electrode structure can be formed at any position in the plane, the common electrode layer and the electrode layer can be led out at any position. For example, by making the lead-out positions of the common electrode layer and the electrode layer close to each other in the plane, it is possible to facilitate the connection to the wiring line.

In the example shown in FIG. 20, a configuration in which the hole portion is provided on the first protective layer side is adopted, but the present invention is not limited thereto. The through-hole electrode structure for leading out the common electrode layer may have a configuration including a hole portion which penetrates the second protective layer, the second electrode layer, and the second piezoelectric layer to expose the common electrode layer and including a conductive member which is electrically connected to the common electrode layer at the hole portion and provided to cover a part of the surface of the second protective layer. Similarly, the through-hole electrode structure for leading out the common electrode layer may have a configuration including a second hole portion which exposes, the second protective layer side, the first electrode layer adjacent to the first protective layer and including a second conductive member which is electrically connected to the first electrode layer at the second hole portion and provided to cover a part of the surface of the second protective layer.

A conductive sheet is used as the conductive member and the second conductive member. The conductive sheet is sheet-like materials formed of a conductive metal material such as a copper foil. Suitable examples of the material of the conductive sheet include copper, aluminum, gold, and silver. In addition, a metal foil tape including a metal foil such as a copper foil tape and a bonding layer may be used.

In addition, a shape of the conductive sheet is not particularly limited as long as the conductive sheet can cover the hole portion or the second hole portion. In addition, a size of the conductive sheet is not particularly limited as long as the conductive sheet can cover the hole portion or the second hole portion and can be connected to the common electrode layer or the electrode layer.

The insulating layer is a sheet-like material formed of a material having insulating properties, such as a tape made of polyimide. Alternatively, the insulating layer may be an insulating layer formed by applying and curing a liquid insulating material. Suitable examples of the material of the insulating layer include polyimide (PI), polyethylene terephthalate (PET), polyethylene naphthalate (PEN), and polypropylene (PP).

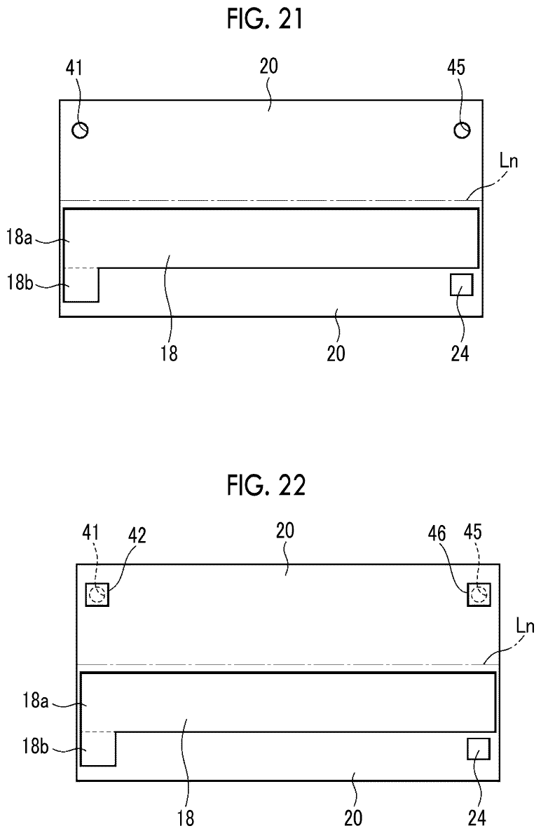

A production method of the piezoelectric element having a through-hole electrode structure, shown in FIG. 20, will be described with reference to FIGS. 21 to 25.

A laminate of the protective layer 28, the electrode layer 24, and the piezoelectric layer 20 is produced in the same manner as in the example shown in FIGS. 6 and 7, and the common electrode layer 18 is disposed on the laminate. In this case, as shown in FIG. 21, the electrode layer 24 does not have a lead-out portion protruding from the piezoelectric layer 20 in the plane direction, and the common electrode layer 18 does not have a lead-out portion protruding from the piezoelectric layer 20 in the plane direction.

In the example shown in FIG. 21, the laminate has a substantially rectangular shape, and a ridge line at a central position in the up-down direction in the figure is folded back as a folding-back line Ln.

In the illustrated example, the common electrode layer 18 is disposed in a region below the folding-back line Ln of the laminate. The common electrode layer 18 has a substantially rectangular main region 18a and a substantially rectangular protruding portion 18b protruding from the main region 18a in the plane direction. A width of the main region 18a of the common electrode layer 18 in the left-right direction substantially coincides with a width of the laminate. On the other hand, a width of the main region 18a of the common electrode layer 18 in the up-down direction is shorter than a width of the region below the folding-back line Ln of the laminate. In addition, the protruding portion 18b of the common electrode layer 18 is formed at one end part (left end part in the left-right direction of the figure) of the short side of the main region 18a on a side opposite to the folding-back line Ln of the laminate.

As shown in FIG. 21, a hole portion 41 and a second hole portion 45 are formed in a region above the folding-back line Ln of the laminate. The hole portion 41 is formed at a position overlapping with the protruding portion 18b of the common electrode layer 18 in a case where the laminate is folded. In addition, the second hole portion 45 is formed at a position not overlapping with the common electrode layer 18 in a case where the laminate is folded. A method of forming the hole portion 41 and the second hole portion 45 is not particularly limited, and the hole portion 41 and the second hole portion 45 may be formed by a known processing method such as punching and punch processing.

In addition, in the region below the folding-back line Ln of the laminate, in a case where the laminate is folded, a recessed portion is formed in a position overlapping with the second hole portion 45 by removing the piezoelectric layer 20 to expose the electrode layer 24. A method of forming the recessed portion is not particularly limited, and the recessed portion may be formed by a known method such as a method of removing the piezoelectric layer 20 using a solvent such as acetone. The recessed portion forms a part of the second hole portion in a case where the laminate is folded.

Next, as shown in FIG. 22, an insulating sheet serving as an insulating layer is disposed at a position of the hole portion 41 and a position of the second hole portion 45 in the laminate. It is preferable that the hole portion 41 is positioned on both surfaces of the laminate. It is preferable that the second hole portion 45 is positioned on the protective layer side.

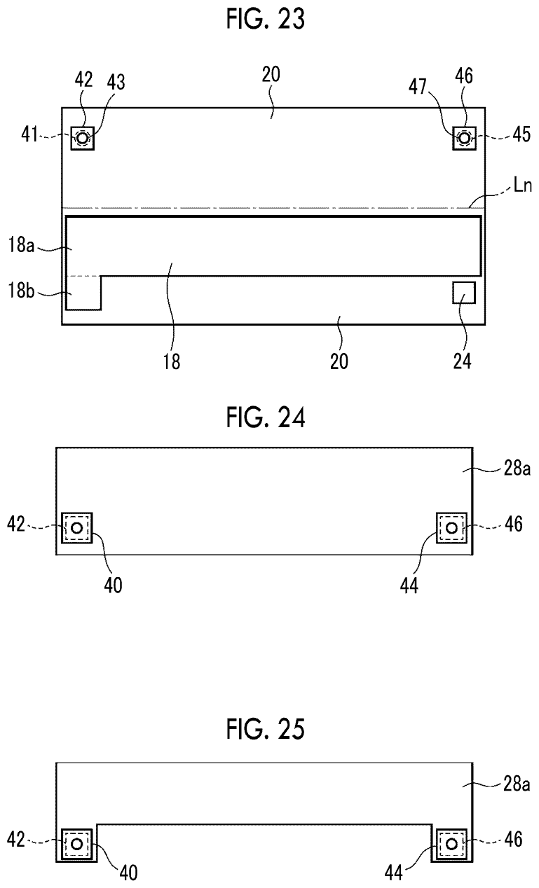

Next, as shown in FIG. 23, through-holes (43 and 47) are formed in the insulating sheet disposed at the position of the hole portion 41 and at the position of the second hole portion 45. A size (diameter) of the through-hole is formed to be smaller than a diameter of the hole portion 41 and a diameter of the second hole portion 45.

Next, as shown in FIG. 24, the laminate is folded along the folding-back line Ln. After the folding, the conductive member 40 is disposed to cover the hole portion 41 (43), and the conductive member 40 and the common electrode layer 18 are electrically connected to each other in the hole portion 41. Similarly, the conductive member 44 is disposed to cover the second hole portion 45 (47) after the folding, and the conductive member 44 and the electrode layer 24 are electrically connected to each other in the second hole portion 45.

As a result, the piezoelectric element having a through-hole electrode structure is produced.

As shown in FIG. 25, a region overlapping with the common electrode layer (main region and protruding portion) and a region other than the region overlapping around the second hole portion 45 may be removed in the in-plane direction.

Hereinbefore, the piezoelectric element according to the embodiment of the present invention has been described in detail, but the present invention is not limited to the above-described examples and various improvements and changes can be made without departing from the spirit of the present invention.

### EXAMPLES

Hereinafter, the present invention will be described in more detail with reference to specific examples of the present invention. The present invention is not limited to the examples, and the materials, the used amounts, the proportions, the treatment contents, the treatment procedures, and the like shown in the following examples can be appropriately changed within a range not departing from the scope of the present invention.

### Example 1

### [Production of Piezoelectric Element]

A piezoelectric film was produced by the method shown in FIGS. 6 to 9 described above.

First, cyanoethylated PVA (CR-V manufactured by Shin-Etsu Chemical Co., Ltd.) was dissolved in dimethylformamide (DMF) at the following compositional ratio. Thereafter, PZT particles as piezoelectric particles were added to the solution at the following compositional ratio, and the solution was stirred using a propeller mixer (rotation speed: 2000 rpm), thereby preparing a coating material for forming a piezoelectric layer.
PZT Particles: 300 parts by mass
Cyanoethylated PVA: 30 parts by mass
DMF: 70 parts by mass

Particles obtained by sintering commercially available PZT raw material powder at 1000° C. to 1200° C. and then crushing and classifying the sintered powder to have an average particle diameter of 5 μm were used as the PZT particles.

On the other hand, a 200 mm×100 mm sheet-like material obtained by performing vacuum vapor deposition on a copper thin film having a thickness of 0.3 μm was prepared on a PET film having a thickness of 4 μm. That is, in the present example, the electrode layer was a copper-deposited thin film having a thickness of 0.3 μm, and the protective layer was a PET film having a thickness of 4 μm. As the PET film, a PET film with a separator, having a thickness of 50 μm, was used.

The electrode layer (copper-deposited thin film) of the sheet-like material was coated with the coating material for forming a piezoelectric layer, which was prepared in advance, using a slide coater. The coating material was applied so that a film thickness of the coating film after drying was 50 μm.

Next, the material obtained by coating the sheet-like material with the coating material was heated and dried on a hot plate at 120° C. to evaporate DMF. In this manner, a laminate in which the electrode layer made of copper was provided on the protective layer made of PET and the piezoelectric layer (polymer-based piezoelectric composite material layer) having a thickness of 50 μm was formed thereon was produced.

The produced piezoelectric layer was subjected to a polarization treatment in the thickness direction.

A copper foil having a thickness of 12 μm was laminated on the piezoelectric layer of the laminate which had been subjected to the polarization treatment, as a common electrode layer. The common electrode layer covered approximately half of the piezoelectric layer in the longitudinal direction, and a region to be a lead-out portion protruded from the piezoelectric layer to the outside. As the copper foil having a thickness of 12 μm, which was to be the common electrode layer, 3EC-3 manufactured by MITSUI MINING & SMELTING CO., LTD. was used.

After the copper foil to be the common electrode layer was laminated on the piezoelectric layer, the piezoelectric layer and the common electrode layer were temporarily bonded to each other by thermal compression bonding at a temperature of 100° C. using a laminator device.

Next, in the laminate, a region where the common electrode layer was not laminated was folded to the common electrode layer side to form a laminate of the piezoelectric layer, the electrode layer, and the protective layer as shown in FIG. 9, in which the common electrode layer was sandwiched by the laminate; and the laminate was subjected to thermal compression bonding at a temperature of 120° C. using a laminator device to bond and adhere the piezoelectric layer and the common electrode layer, thereby producing a piezoelectric element having a size of 100 mm×100 mm.

### Example 2

A piezoelectric element was produced in the same manner as in Example 1, except that the thickness of the common electrode layer was set to 1.5 μm.

As a copper foil having a thickness of 1.5 μm, MicroThin (MT18FL manufactured by MITSUI MINING & SMELTING CO., LTD.) having a precipitated ultra-thin copper foil (thickness: 1.5 μm) on a surface of the copper foil was used, and the copper foil was laminated on and temporarily adhered to the piezoelectric layer and then peeled off from the copper foil as a base material, thereby laminating the ultra-thin copper foil having a thickness of 1.5 μm on the piezoelectric layer.

### Comparative Example 1

A piezoelectric film was produced by the method described in WO2020/196850A using the same coating material, electrode layer, and protective layer as in Example 1 as the coating material, the electrode layer, and the protective layer for forming the piezoelectric layer.

The produced piezoelectric film was cut into a size of 200 mm×100 mm, and folded at a substantially center portion in a longitudinal direction to produce a piezoelectric element. The folded piezoelectric film was bonded with an adhesive (KuranBeter G5 manufactured by KURABO INDUSTRIES LTD.). A thickness of the adhesive layer was approximately 30 μm.

### Evaluation

For the produced piezoelectric elements of each of Examples and Comparative example, a thickness and a sound pressure were evaluated.

### <Thickness>

The thickness of each piezoelectric element was measured using a digitmatic indicator ID-C112RXB manufactured by Mitutoyo Corporation.

### <Sound Pressure>

The produced piezoelectric element was bonded to a vibration plate to produce an electroacoustic transducer. As the vibration plate, a plate-shaped member having a size of 500 mm×450 mm, a thickness of 0.8 mm, and a material of aluminum (A5052) was used. A lateral direction of the vibration plate and a longitudinal direction of the piezoelectric element were aligned, and the piezoelectric element was bonded to the center of the laminated portion, aligned with the center of the vibration plate. As a bonding layer which bonds the piezoelectric element and the vibration plate to each other, a pressure-sensitive adhesive tape TESA 70420 (manufactured by TESA, Young's modulus: approximately 5 MPa) was used.

In addition, as Example 2-2, an electroacoustic transducer was produced using a KuranBeter G5 (manufactured by KURABO INDUSTRIES LTD., Young's modulus: approximately 1 GPa) as the bonding layer (adhesive layer) for bonding the piezoelectric element and the vibration plate of Example 2 to each other.

The Young's modulus was a storage elastic modulus (Young's modulus) at a frequency of 1 kHz measured by a dynamic viscoelasticity test. The storage elastic modulus (Young's modulus) may be measured by a known method. As an example, the measurement may be performed using a dynamic viscoelasticity measuring device DMS6100 (manufactured by SII Nanotechnology Inc.).

Examples of measurement conditions include conditions with a measurement frequency of 0.1 Hz to 20 Hz (0.1 Hz, 0.2 Hz, 0.5 Hz, 1 Hz, 2 Hz, 5 Hz, 10 Hz, and 20 Hz), a measurement temperature of −50° C. to 150° C., a temperature rising rate of 2° C./min (in a nitrogen atmosphere), a sample size of 40 mm×10 mm (including the clamped region), and a chuck-to-chuck distance of 20 mm.

A Sine sweep signal of a frequency of 1 kHz and an applied voltage of 50 Vrms was input to the piezoelectric element, and the sound pressure was measured with a microphone placed at a distance of 1 m from the center of the vibration plate.

The results are shown in Table 1.

TABLE 1

| | Configuration of | | | | | |
|---|---|---|---|---|---|---|
| | piezoelectric element | | Electroacoustic transducer | | | |
| | Common electrode | | Bonding layer (adhesive | | Evaluation | |
| | layer | | layer) | | | Sound |
| | Presence | Thickness | | Young's | Thickness | pressure |
| | or absence | μm | Type | modulus | μm | dB |
| Example 1 | Presence | 1.2 | TESA70420 | 5 MPa | 120 | 77 |
| Example 2 | Presence | 1.5 | TESA70420 | 5 MPa | 110 | 82 |
| Example 2-2 | Presence | 1.5 | KuranBeter | 1 GPa | 110 | 85 |
| | | | G5 | | | |
| Comparative | Absence | — | TESA70420 | 5 MPa | 147 | 78 |
| Example 1 | | | | | | |

From Table 1, it was found that, in Examples of the present invention, the thickness can be reduced while maintaining the sound pressure as compared with Comparative Example.

In Comparative Example 1, the sound pressure could be increased, but the thickness was increased.

In addition, from the comparison between Example 1 and Example 2, it was found that, as the thickness of the common electrode layer was smaller, the vibration of the piezoelectric element was less likely to be constrained, and the sound pressure was improved. In addition, it was found that the thickness of the piezoelectric element is also reduced.

In addition, from the comparison between Example 2 and Example 2-2, it was found that the hardness of the adhesive layer in a case of bonding the piezoelectric element according to the embodiment of the present invention to the vibration plate was preferably 0.5 GPa or more.

From the above, the effects of the present invention are clear.

The piezoelectric element according to the embodiment of the present invention is suitably used as the following, for example: as various sensors such as a sound wave sensor, an ultrasonic wave sensor, a pressure sensor, a tactile sensor, a strain sensor, and a vibration sensor (which are useful particularly for an infrastructure examination such as crack detection and a manufacturing site inspection such as foreign matter contamination detection); acoustic devices such as microphones, pickups, speakers, and exciters (as specific applications, noise cancellers (used for cars, trains, airplanes, robots, and the like), artificial voice bands, buzzers to prevent pests and beasts from invading, furniture, wallpaper, photo, helmet, goggles, headrest, signage, robot, and the like are exemplified); haptics used for application to automobiles, smartphones, smart watches, games, and the like; ultrasonic transducers such as ultrasound probe and hydrophones; actuators used for prevention of attachment of water droplets, transportation, agitation, dispersion, polishing, and the like; damping materials (dampers) used for containers, vehicles, buildings, sports equipment such as skis and rackets; and vibration power generator used for application to roads, floors, mattresses, chairs, shoes, tires, wheels, computer keyboards, and the like.

### EXPLANATION OF REFERENCES

18: common electrode layer
18a: main region
18b: protruding portion
19: lead-out portion
20: piezoelectric layer
20a: first piezoelectric layer
20b: second piezoelectric layer
24: electrode layer
24a: first electrode layer
24b: second electrode layer
25: lead-out portion
28: protective layer
28a: first protective layer
28b: second protective layer
29: protruding portion
34: matrix
36: piezoelectric particle
40: conductive member
41: hole portion
42: insulating layer
43: through-hole
44: second conductive member
45: second hole portion
46: insulating layer
47: through-hole
50, 50a to 50f: piezoelectric element
52: adhesive layer
54, 62, 70: insulating sheet
56, 64: conductive sheet
58, 66: solder
60, 68: lead wire
100: electroacoustic transducer
102: vibration plate
104: adhesive layer
Ln: folding-back line

What is claimed is:

1. A piezoelectric element comprising:
a common electrode layer;
a first piezoelectric layer which consists of a polymer-based piezoelectric composite material containing piezoelectric particles in a matrix containing a polymer material and is provided on one surface of the common electrode layer;
a first electrode layer which is provided on a surface of the first piezoelectric layer on a side opposite to the common electrode layer;
a first protective layer which is provided on a surface of the first electrode layer on a side opposite to the first piezoelectric layer;
a second piezoelectric layer which consists of a polymer-based piezoelectric composite material containing piezoelectric particles in a matrix containing a polymer material and is provided on the other surface of the common electrode layer;
a second electrode layer which is provided on a surface of the second piezoelectric layer on a side opposite to the common electrode layer; and
a second protective layer which is provided on a surface of the second electrode layer on a side opposite to the second piezoelectric layer.

2. The piezoelectric element according to claim 1,
wherein the first piezoelectric layer and the second piezoelectric layer are an integrated piezoelectric layer,
the first electrode layer and the second electrode layer are an integrated electrode layer,
the first protective layer and the second protective layer are an integrated protective layer, and
a laminate of the piezoelectric layer, the electrode layer, and the protective layer is folded to sandwich the common electrode layer.

3. The piezoelectric element according to claim 1,
wherein the first piezoelectric layer and the second piezoelectric layer are polarized in a thickness direction, and
a polarization direction in the first piezoelectric layer and a polarization direction in the second piezoelectric layer are opposite to each other.

4. The piezoelectric element according to claim 1,
wherein a thickness of the common electrode layer is 10 μm or less.

5. The piezoelectric element according to claim 1,
wherein the common electrode layer consists of a metal material, and
crystal grains of the metal material are connected to each other from one surface of the common electrode layer to the other surface.

6. The piezoelectric element according to claim 1,
wherein the common electrode layer has no interface in a case of being viewed in a cross section perpendicular to a thickness direction.

7. The piezoelectric element according to claim 1,
wherein a sheet resistance of the common electrode layer is 100 mΩ/□ or less.

8. A piezoelectric element obtained by laminating two or more of the piezoelectric elements according to claim 1.

9. The piezoelectric element according to claim 1, further comprising:
a hole portion which penetrates the first protective layer, the first electrode layer, and the first piezoelectric layer or penetrates the second protective layer, the second electrode layer, and the second piezoelectric layer to expose the common electrode layer; and
a conductive member which is electrically connected to the common electrode layer in the hole portion is provided to cover a part of a surface of the first protective layer or a part of a surface of the second protective layer.

10. The piezoelectric element according to claim 9, further comprising:
an insulating layer which is provided between the first electrode layer and the conductive member or between the second electrode layer and the conductive member and is exposed on a side surface of the hole portion.

11. The piezoelectric element according to claim 1, further comprising:
a second hole portion which exposes, from one side of the first protective layer or the second protective layer, an electrode layer adjacent to the other side; and
a second conductive member which is electrically connected to the electrode layer in the second hole portion is provided to cover a part of a surface of the protective layer on the one side.

12. The piezoelectric element according to claim 11, further comprising:
an insulating layer which is provided between the first electrode layer and the second conductive member or between the second electrode layer and the second conductive member and is exposed on a side surface of the second hole portion.

13. An electroacoustic transducer comprising:
a vibration plate; and
the piezoelectric element according to claim 1 attached to the vibration plate.

14. The electroacoustic transducer according to claim 13, further comprising:
a bonding layer which bonds the piezoelectric element and the vibration plate to each other,
wherein a Young's modulus of the bonding layer is 0.1 GPa to 10 GPa.

15. The piezoelectric element according to claim 2,
wherein the first piezoelectric layer and the second piezoelectric layer are polarized in a thickness direction, and
a polarization direction in the first piezoelectric layer and a polarization direction in the second piezoelectric layer are opposite to each other.

16. The piezoelectric element according to claim 2,
wherein a thickness of the common electrode layer is 10 μm or less.

17. The piezoelectric element according to claim 2,
wherein the common electrode layer consists of a metal material, and
crystal grains of the metal material are connected to each other from one surface of the common electrode layer to the other surface.

18. The piezoelectric element according to claim 2,
wherein the common electrode layer has no interface in a case of being viewed in a cross section perpendicular to a thickness direction.

19. The piezoelectric element according to claim 2,
wherein a sheet resistance of the common electrode layer is 100 mΩ/□ or less.

20. A piezoelectric element obtained by laminating two or more of the piezoelectric elements according to claim 2.
